(19) United States
(12) Patent Application Publication
(10) Pub. No.: US 2025/0311436 A1
(43) Pub. Date: Oct. 2, 2025

(54) HYBRID BULK SEMICONDUCTOR AND SEMICONDUCTOR ON INSULATOR (SOI) SUBSTRATE AND METHODS OF FORMATION

(71) Applicant: Taiwan Semiconductor Manufacturing Company, Ltd., Hsinchu (TW)

(72) Inventors: Yu-Hung CHENG, Tainan City (TW); Szu-Yu WANG, Hsinchu City (TW); Ching I LI, Tainan (TW)

(21) Appl. No.: 18/618,312

(22) Filed: Mar. 27, 2024

(51) Int. Cl. H01L 27/12; H01L 21/84

(52) U.S. Cl. CPC H10D 87/00; H10D 86/01

(57) ABSTRACT

A two-part technique is used to form a semiconductor on insulator (SOI) region in a bulk semiconductor substrate with minimal to no dislocation or void formation. Recesses are formed in the bulk semiconductor substrate. The recesses are filled with first portions of an insulator layer of the SOI region, and the first portions are then etched back such that the first portions occupy only a bottom portion of the recesses such that semiconductor material of the sidewalls of the recesses are exposed. A top semiconductor layer is epitaxially grown over the first portions in the recesses. Subsequently, recesses between the first portions are formed through the top semiconductor layer into the bulk semiconductor substrate and filled in with second portions of the insulator layer. An epitaxial regrowth operation is performed to regrow and merge the top semiconductor layer over the insulator layer.

### BACKGROUND

Integrated circuits have traditionally been formed on bulk semiconductor substrates. In recent years, semiconductor on insulator (SOI) substrates have emerged as an alternative to bulk semiconductor substrates. An SOI substrate typically includes a semiconductor substrate, an insulator layer (sometimes referred to as a buried oxide (BOX) layer) over the semiconductor substrate, and a semiconductor layer overlying the insulator layer. Among other things, an SOI substrate may provide reduced parasitic capacitance, reduced leakage current, reduced latch up, and/or increased semiconductor device performance (e.g., lower power consumption and higher switching speed) relative to a bulk semiconductor substrate.

### BRIEF DESCRIPTION OF THE DRAWINGS

Aspects of the present disclosure are best understood from the following detailed description when read with the accompanying figures. It is noted that, in accordance with the standard practice in the industry, various features are not drawn to scale. In fact, the dimensions of the various features may be arbitrarily increased or reduced for clarity of discussion.

FIG. 1 is a diagram of an example implementation of a semiconductor substrate described herein.

FIGS. 2A and 2B are diagrams of an example semiconductor device described herein.

FIGS. 3A-3M are diagrams of an example implementation of forming a hybrid substrate of a semiconductor device described herein.

FIGS. 4A-4H are diagrams of an example implementation of forming semiconductor devices on a hybrid substrate of a semiconductor device described herein.

FIG. 5 is a flowchart of an example process associated with forming a hybrid substrate described herein.

FIG. 6 is a flowchart of an example process associated with forming a hybrid substrate described herein.

### DETAILED DESCRIPTION

The following disclosure provides many different embodiments, or examples, for implementing different features of the provided subject matter. Specific examples of components and arrangements are described below to simplify the present disclosure. These are, of course, merely examples and are not intended to be limiting. For example, the formation of a first feature over or on a second feature in the description that follows may include embodiments in which the first and second features are formed in direct contact, and may also include embodiments in which additional features may be formed between the first and second features, such that the first and second features may not be in direct contact. In addition, the present disclosure may repeat reference numerals and/or letters in the various examples. This repetition is for the purpose of simplicity and clarity and does not in itself dictate a relationship between the various embodiments and/or configurations discussed.

Further, spatially relative terms, such as “beneath,” “below,” “lower,” “above,” “upper” and the like, may be used herein for ease of description to describe one element or feature's relationship to another element(s) or feature(s) as illustrated in the figures. The spatially relative terms are intended to encompass different orientations of the device in use or operation in addition to the orientation depicted in the figures. The apparatus may be otherwise oriented (rotated 90 degrees or at other orientations) and the spatially relative descriptors used herein may likewise be interpreted accordingly.

Some semiconductor devices are formed on semiconductor on insulator (SOI) substrates, and other semiconductor devices are formed on bulk semiconductor (e.g., silicon (Si)) substrates. Integrating semiconductor devices into a hybrid substrate that includes an SOI region and a bulk semiconductor region can be challenging. Forming the hybrid substrate usually includes starting with a baseline substrate, and modifying the baseline substrate to form either an SOI region or a bulk semiconductor region. For example, a portion of an SOI substrate may be modified for forming a bulk semiconductor region in the SOI substrate. As another example, a portion of a bulk semiconductor substrate may be modified for forming an SOI region in the bulk semiconductor substrate. However, these techniques may be costly and may involve many semiconductor processing operations to achieve a hybrid substrate on which semiconductor devices may then be formed. Moreover, these techniques may result in defects in a hybrid substrate, such as unwanted epitaxial overgrowth and/or dislocation between various layers of the hybrid substrate.

In some implementations described herein, a hybrid substrate is formed by forming an SOI region in a bulk semiconductor substrate. A two-part technique is used to form the SOI region with minimal to no dislocation or void formation. The bulk semiconductor substrate may be patterned and etched to form first recesses in the bulk semiconductor substrate. The first recesses are filled with first portions of an insulator layer (e.g., to be a portion of buried oxide (BOX) layer) of the SOI region, and the first portions are then etched back such that the first portions occupy only a bottom portion of the first recesses such that semiconductor material of the sidewalls of the first recesses are exposed. The semiconductor material of the sidewalls of the first recesses provide an epitaxial growth substrate/surface on and in between which a semiconductor layer is epitaxially grown in the first recesses above first portions and over the filled first recesses. Subsequently, second recesses between the first portions are formed through the top semiconductor layer into the bulk semiconductor substrate and filled in with second portions of the insulator layer using similar techniques. An epitaxial regrowth operation is performed to regrow and merge the top semiconductor layer over the insulator layer.

In this way, the two-part technique for forming the SOI region in the bulk semiconductor substrate enables the SOI region to be formed using low-cost semiconductor processing techniques, thereby reducing the complexity and/or cost of forming the hybrid substrate relative to other techniques. Moreover, the two-part technique for forming the SOI region in the bulk semiconductor substrate enables the SOI region to be formed without unwanted epitaxial lateral overgrowth, thereby eliminating additional semiconductor processing steps for removing the unwanted epitaxial lateral overgrowth. This further reduces the complexity and/or cost of forming the hybrid substrate relative to other techniques. In addition, the two-part technique for forming the SOI region in the bulk semiconductor substrate enables the SOI region the be formed with reduced likelihood of dislocation in the SOI region relative to other techniques, thereby increasing the yield of hybrid substrates.

This two-part technique can be further extrapolated to have more than two parts where more than two portions of the insulator layer can be sequentially deposited to form a BOX having epitaxially grown semiconductor around the insulator portions.

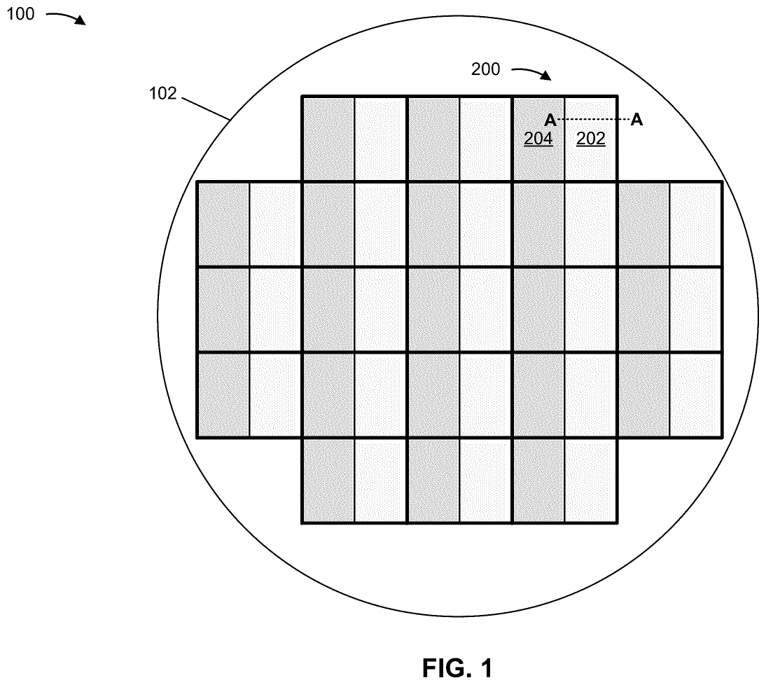

FIG. 1 is a diagram of an example implementation 100 of a semiconductor substrate 102 described herein. The semiconductor substrate 102 may include a semiconductor substrate (e.g., a silicon substrate, a silicon germanium substrate) on which a plurality of semiconductor devices 200 are manufactured. The semiconductor devices 200 may each include a semiconductor die such as a logic die (e.g., a processor, a central processing unit (CPU) die, a graphics processing unit (GPU) die), a memory die (e.g., a dynamic random access memory (DRAM) die, a static random access memory (SRAM) die, a high band width memory (HBM) die), a display panel die (e.g., a display panel driver including a driver integrated circuit (IC), a line driver IC, a level shifter IC), a radio frequency (RF) die (e.g., a baseband processor, an RF front-end module), an input/output (I/O) die, and/or another type of semiconductor die that includes one or more high voltage transistor structures.

As shown in FIG. 1, a semiconductor device 200 includes a plurality of regions, including an active semiconductor region 202 and a shallow trench isolation (STI) region 204. The active semiconductor region 202 and the STI region 204 are adjacent in the top-down view in FIG. 1. The STI region 204 provides electrical isolation between adjacent active semiconductor regions 202 and may include one or more dielectric materials. The active semiconductor region(s) 202 and the STI region(s) 204 may extend in the same direction on the substrate 102 such that the active semiconductor region(s) 202 and the STI region(s) 204 are parallel.

As indicated above, FIG. 1 is provided as an example. Other examples may differ from what is described with regard to FIG. 1.

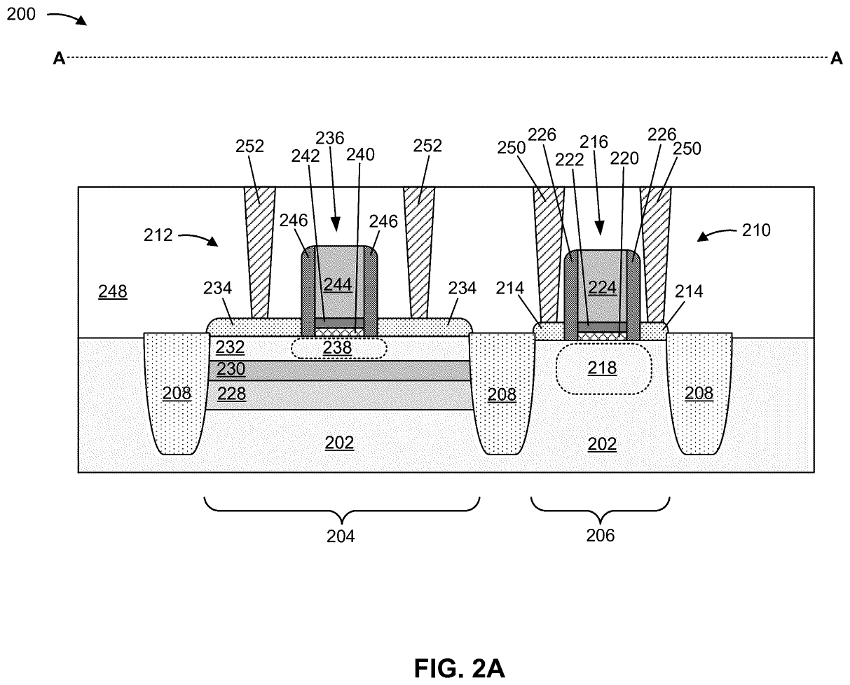

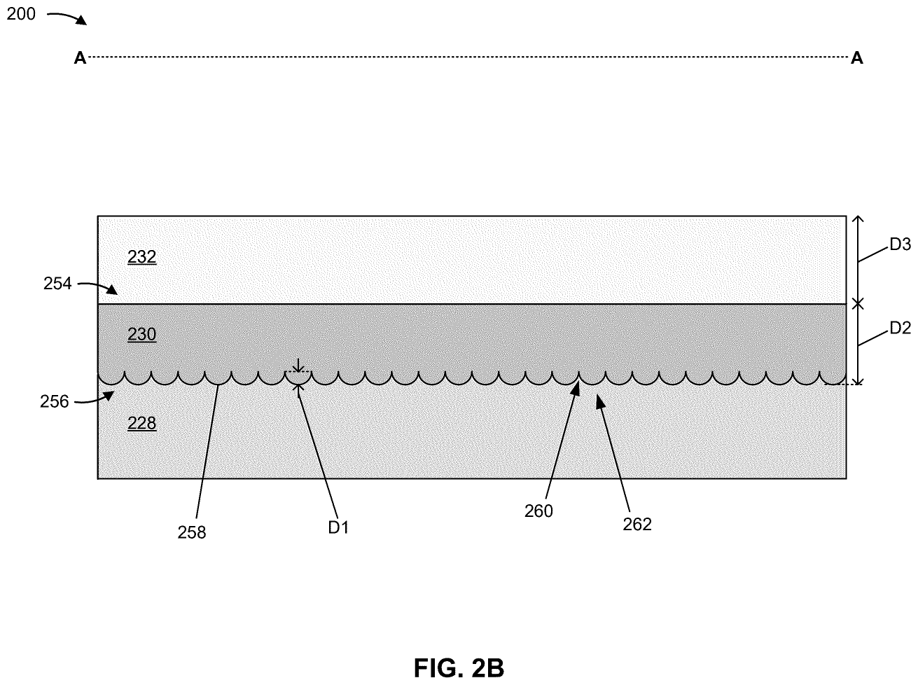

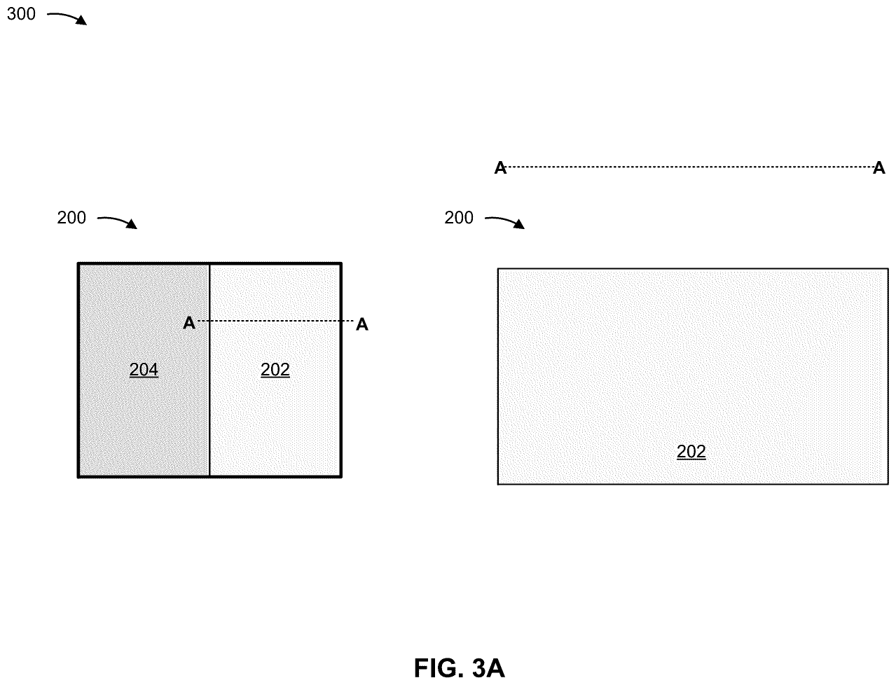

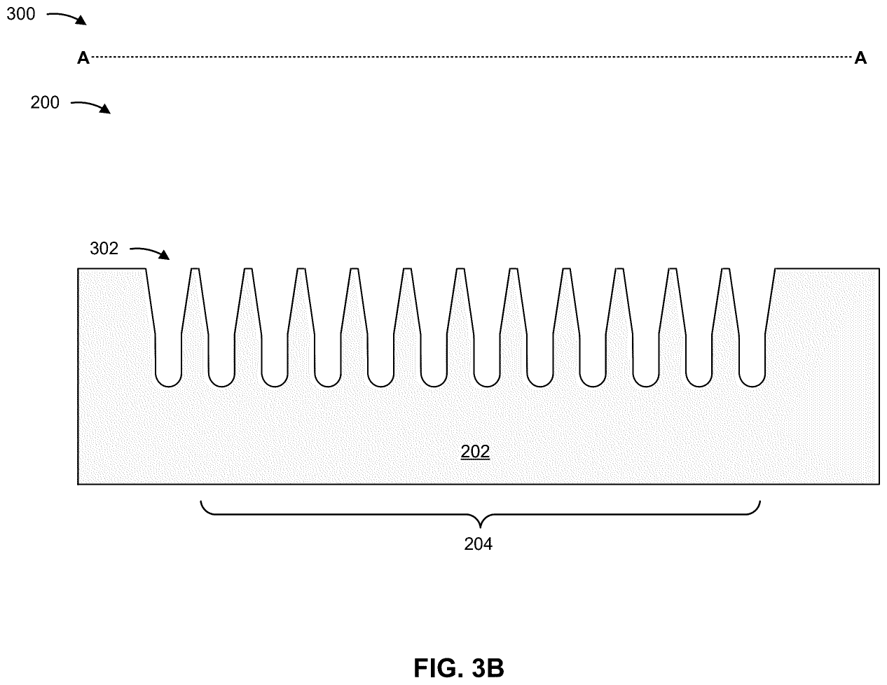

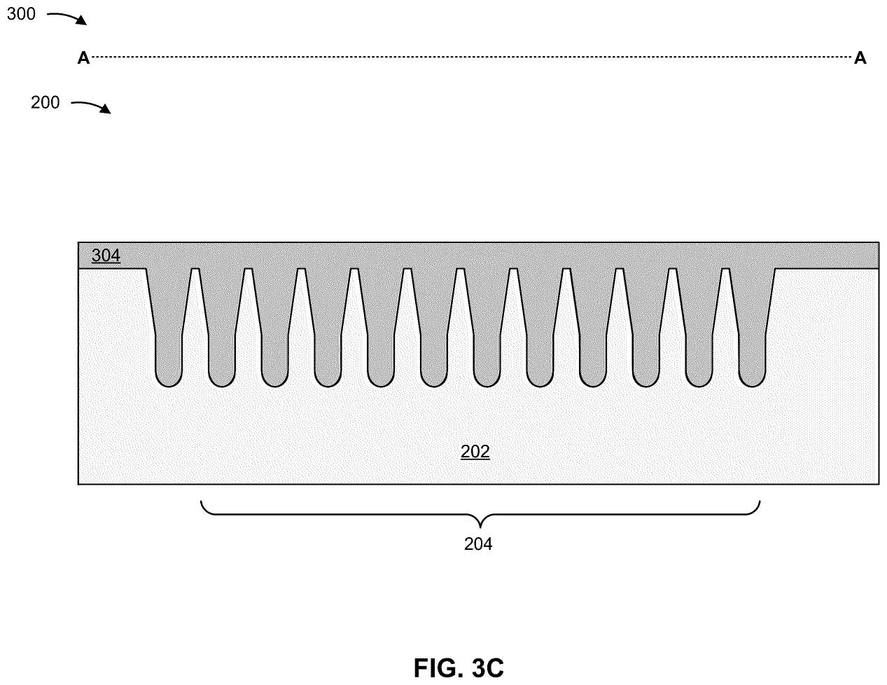

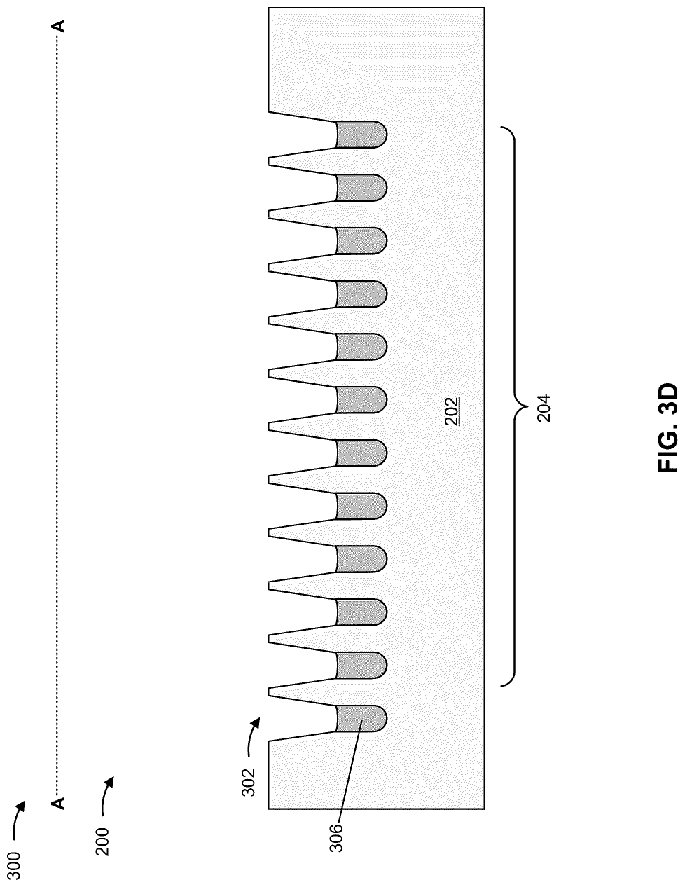

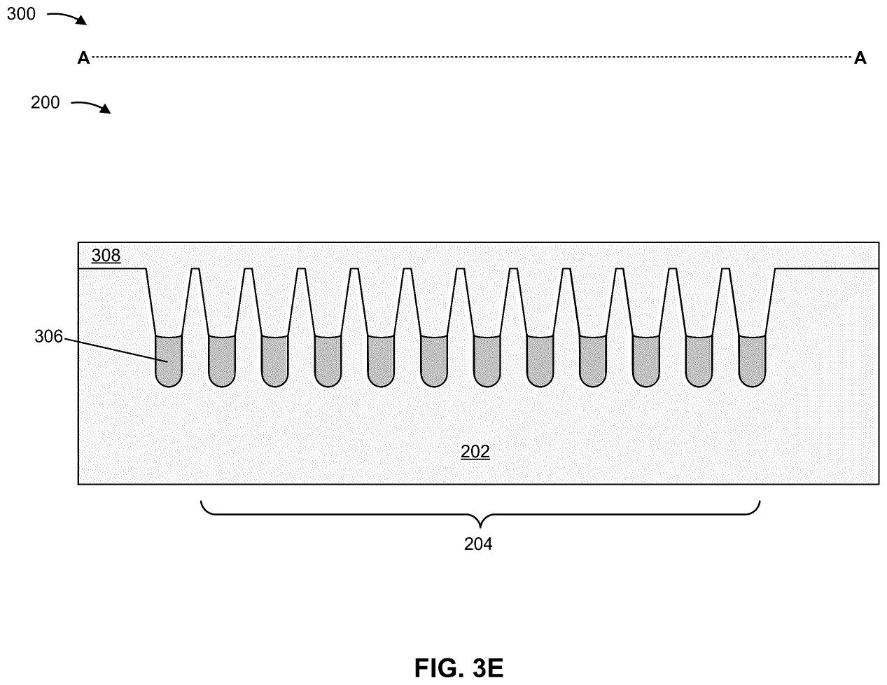

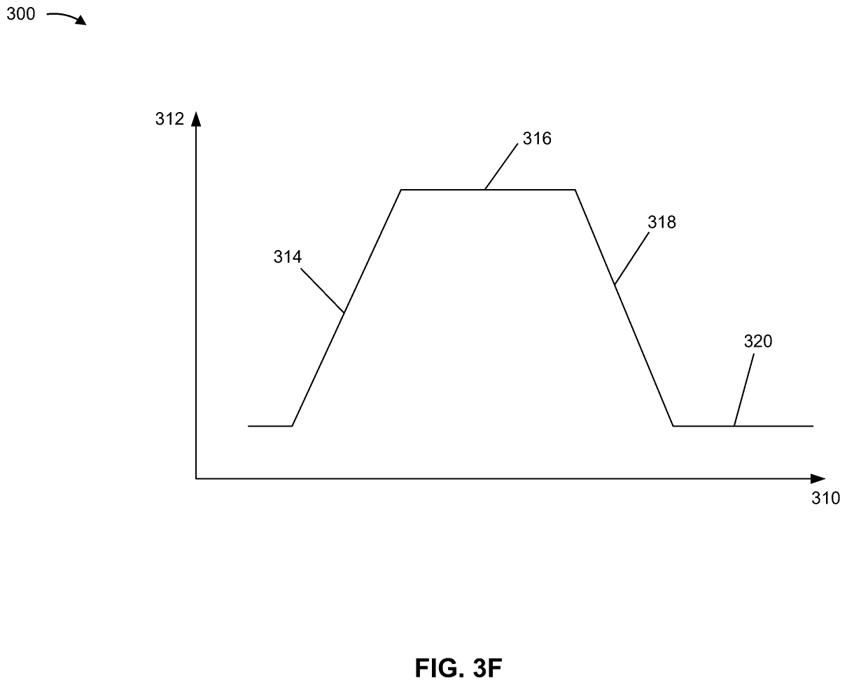

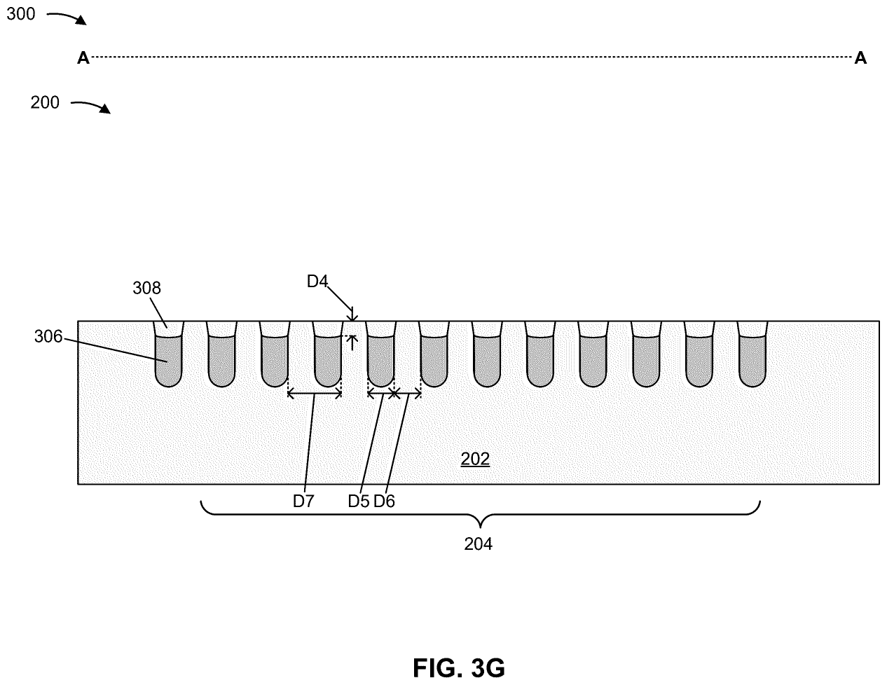

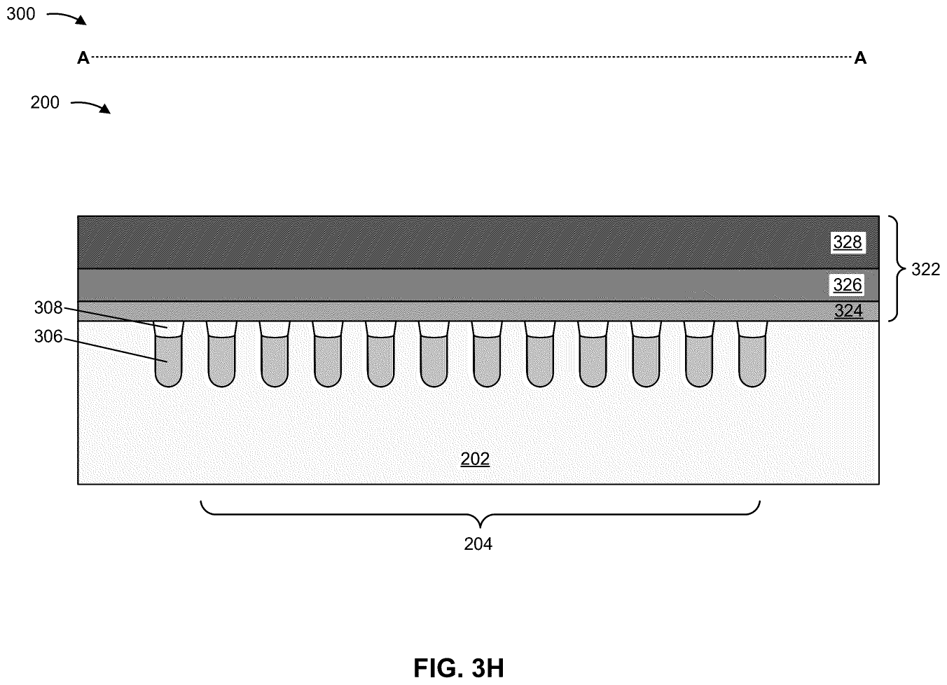

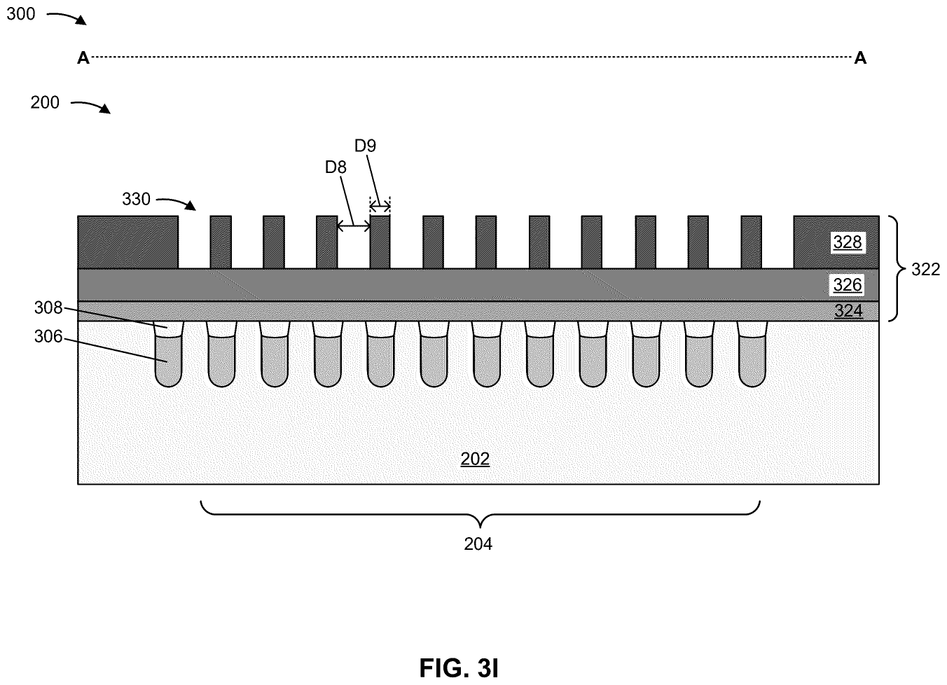

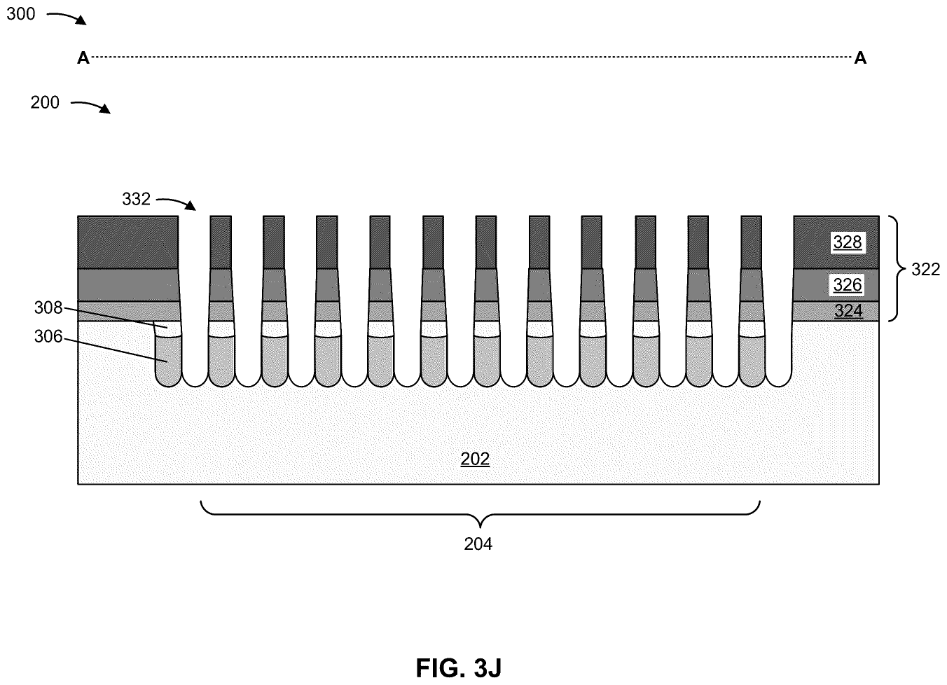

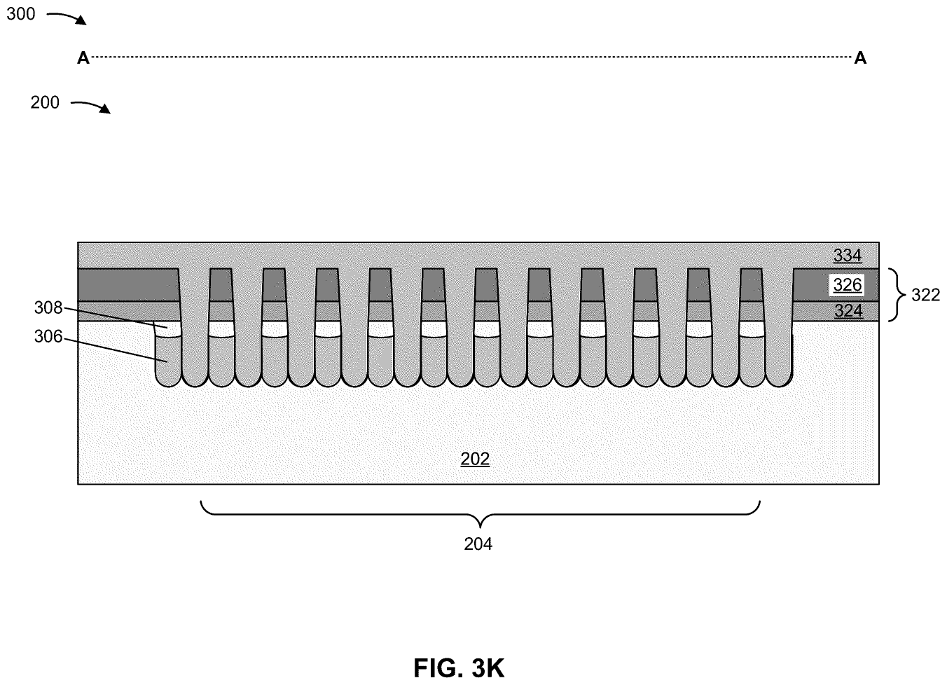

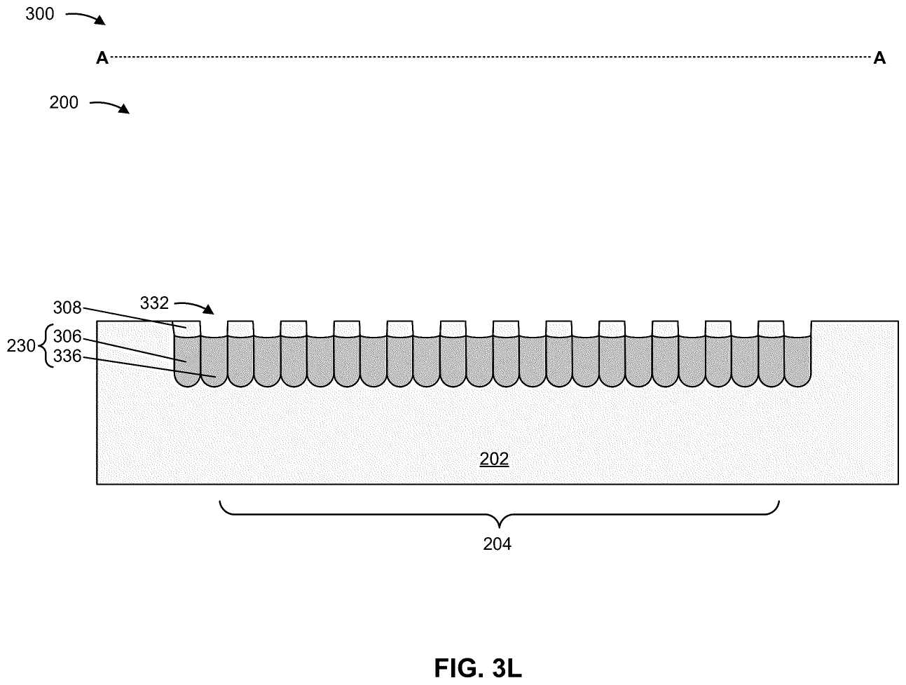

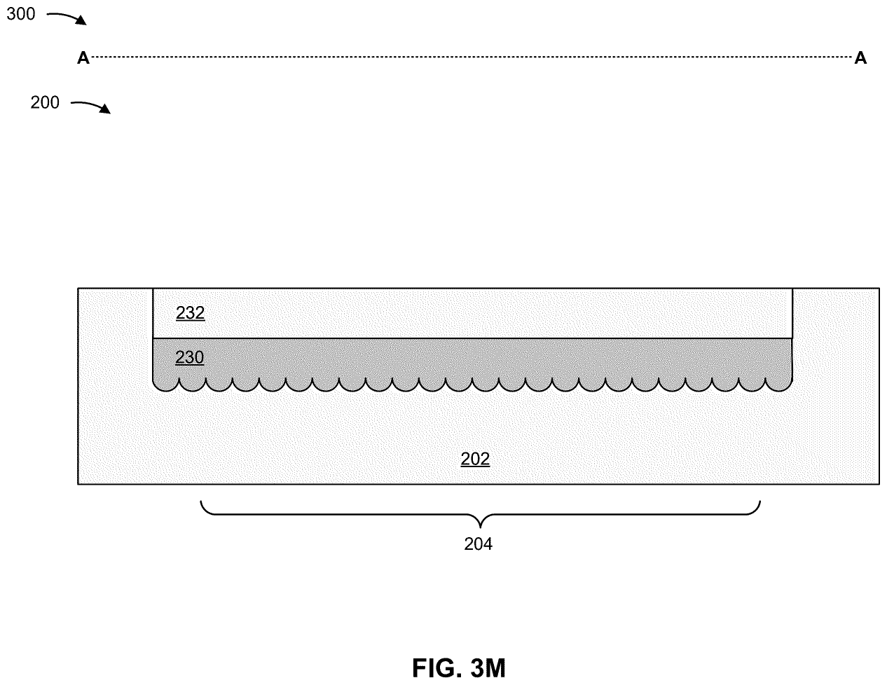

FIGS. 2A and 2B are diagrams of an example semiconductor device 200 described herein. The semiconductor device 200 may be formed on the substrate 102 and may include an active semiconductor region 202. FIG. 2A illustrates a cross-section view of the semiconductor device 200 along the line A-A in FIG. 1. As shown in FIG. 2A, the semiconductor device 200 includes an SOI region 204 adjacent to a bulk semiconductor region 206 in the active semiconductor region 202. Thus, the semiconductor device 200 includes a hybrid substrate. In particular, the semiconductor device 200 includes a hybrid bulk semiconductor and SOI substrate. As described in connection with FIGS. 3A-3M, the hybrid substrate is formed from the active semiconductor region 202. In particular, the active semiconductor region 202 is provided as a bulk semiconductor substrate, and the SOI region 204 is formed in the bulk semiconductor substrate adjacent to the bulk semiconductor region 206 using semiconductor processing techniques described herein.

The active semiconductor region 202 includes a bulk semiconductor material. For example, the active semiconductor region 202 may include a bulk silicon (Si) substrate, a substrate formed of a material including silicon such as silicon germanium (SiGe), a III-V compound semiconductor material substrate such as gallium arsenide (GaAs), a germanium (Ge) substrate, a silicon germanium (SiGe) substrate, and/or or another type of semiconductor substrate.

Isolation regions 208 may be provided in the active semiconductor region 202 to electrically isolate, thermally isolate, and/or otherwise isolate the bulk semiconductor region 206 and the SOI region 204. The isolation regions 208 may include STI regions, deep trench isolation (DTI) regions, and/or another type of isolation regions. The isolation regions 208 may include structures that extend into the active semiconductor region 202 in between the bulk semiconductor region 206 and the SOI region 204. The isolation regions 208 may include one or more dielectric materials, such as a silicon oxide (SiOₓ), a silicon nitride (SiₓN_{y}), a silicon oxynitride (SiON), fluoride-doped silicate glass (FSG), a low dielectric constant (low-k) dielectric material, and/or another suitable insulating material. The isolation regions 208 may include a multi-layer structure, for example, having one or more liner layers.

As further shown in FIG. 2A, the semiconductor device 200 may include one or more bulk semiconductor devices 210 included in the bulk semiconductor region 206, and one or more SOI semiconductor devices 212 included in the SOI region 204. In some implementations, the bulk semiconductor devices 210 include electrostatic discharge (ESD) protection circuitry (e.g., diodes, bipolar junction transistors (BJTs)), high voltage transistors, analog circuitry, and/or another type of bulk semiconductor devices. “High voltage transistor” may refer to a transistor structure that operates based on a relatively high voltage, such as approximately 8 volts or greater, among other examples.

In some implementations, the SOI semiconductor devices 212 are RF devices (e.g., RF switches, RF amplifiers), low voltage transistors, silicon photonics devices (e.g., optical modulators, waveguides), complementary metal oxide semiconductor (CMOS) logic circuitry, and/or another type of SOI semiconductor devices. “Low voltage transistor” may refer to a transistor that operates based on a relative low voltage, such as approximately 6 volts or less, among other examples. A low voltage transistor may include a low voltage planar transistor, a low voltage fin field effect transistor (finFET), a low voltage nanostructure transistor, and/or a low voltage transistor of another type. In some implementations, a low voltage nanostructure transistor may be referred to as a gate all around (GAA) transistor structure or GAA field effect transistor (GAAFET or GAA FET) structure, a low voltage nanowire transistor structure, a low voltage nanosheet transistor structure, a low voltage multi-bridge channel transistor structure, a nanoribbon transistor structure, and/or another type of low voltage nanostructure transistor structure.

FIG. 2A illustrates an example bulk semiconductor device 210. The bulk semiconductor device 210 may include one or more source/drain regions 214, a gate structure 216 between the source/drain regions 214, and a channel region 218 in the bulk semiconductor region 206 of the active semiconductor region 202 under the gate structure 216. “Source/drain region(s)” may refer to a source or a drain, individually or collectively depending upon the context. In some implementations, the source/drain regions 214 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the bulk semiconductor device 210 may include a p-type metal oxide semiconductor (PMOS) transistor that includes p-type source/drain regions, an n-type metal oxide semiconductor (NMOS) transistor that includes n-type source/drain regions, and/or another type of transistor.

The gate structure 216 may include one or more layers 220-224, such as a gate dielectric layer, a gate electrode layer, a hard mask layer, a capping layer, and/or a work function tuning layer, among other examples. In some implementations, the gate structure 216 includes a polysilicon gate electrode. In some implementations, the gate structure 216 includes a metal gate structure in which the gate electrode layer is a metal gate electrode having one or more work function tuning layers and a high dielectric constant (high-k) gate dielectric layer.

Sidewall spacers 226 may be included on sides of the gate structure 216 to electrically isolate the gate structure 216 from nearby structures, such as the source/drain regions 214 and/or source/drain contacts that are electrically connected with the source/drain regions 214, among other examples. The sidewall spacers 226 may include a silicon nitride (SiₓN_{y}), a silicon oxycarbide (SiC), and/or another suitable spacer material.

As further shown in FIG. 2A, the SOI region 204 includes an SOI layer stack that includes a portion of the bulk semiconductor substrate of the active semiconductor region 202, a semiconductor grounding layer 228, an insulator layer 230 (e.g., a BOX layer), and a semiconductor layer 232 over and/or on the insulator layer 230. The semiconductor grounding layer 228 may include a doped region of the bulk semiconductor substrate of the active semiconductor region 202 that is doped with p-type dopants and/or n-type dopants to provide a grounding plane for the SOI semiconductor device(s) 212. The insulator layer 230 includes one or more dielectric materials, such as a silicon oxide (SiOₓ such as SiO₂), a silicon nitride (SiₓN_{y} such as Si₃N₄), silicon oxycarbonitride (SiOCN), silicon oxynitride (SiON), and/or silicon carbon nitride SiCN), among other examples. The semiconductor layer 232 may include a same semiconductor material (e.g., silicon (Si), among other examples) as the bulk semiconductor substrate of the active semiconductor region 202 and/or a different semiconductor material.

The SOI semiconductor device 212 is included above and/or on the SOI layer stack in the SOI region 204. The SOI semiconductor device 212 may include one or more source/drain regions 234, a gate structure 236 between the source/drain regions 234, and a channel region 238 in the semiconductor layer 232 under the gate structure 236. The insulator layer 230 enables the channel region 238 to be confined in the semiconductor layer 232, which may provide low current leakage and/or may enable a lower gate voltage to be used for the SOI semiconductor device 212 than other semiconductor devices, among other examples. In some implementations, the source/drain regions 234 include silicon (Si) with one or more dopants, such as a p-type material (e.g., boron (B) or germanium (Ge), among other examples), an n-type material (e.g., phosphorous (P) or arsenic (As), among other examples), and/or another type of dopant. Accordingly, the SOI semiconductor device 212 may include a p-type metal oxide semiconductor (PMOS) transistor that includes p-type source/drain regions, an n-type metal oxide semiconductor (NMOS) transistor that includes n-type source/drain regions, and/or another type of transistor.

The gate structure 236 may include one or more layers 240-244, such as a gate dielectric layer, a gate electrode layer, a hard mask layer, a capping layer, and/or a work function tuning layer, among other examples. In some implementations, the gate structure 236 includes a polysilicon gate electrode. In some implementations, the gate structure 236 includes a metal gate structure in which the gate electrode layer is a metal gate electrode having one or more work function tuning layers and a high-k gate dielectric layer.

Sidewall spacers 246 may be included on sides of the gate structure 236 to electrically isolate the gate structure 236 from nearby structures, such as the source/drain regions 234 and/or source/drain contacts that are electrically connected with the source/drain regions 234, among other examples. The sidewall spacers 246 may include a silicon nitride (SiₓN_{y}), a silicon oxycarbide (SiC), and/or another suitable spacer material.

A dielectric region 248 may be included over and/or on the bulk semiconductor device(s) 210 and the SOI semiconductor device(s) 212. The dielectric region 248 may be included to provide additional electrical isolation and/or additional thermal isolation, as well as provide a substantially planar surface on which subsequent layers and/or structures of the semiconductor device 200 may be formed. The dielectric region 248 may include an interlayer dielectric (ILD) and/or another type of dielectric region. The dielectric region 248 includes one or more dielectric materials, such as a silicon oxide (SiOₓ such as SiO₂), a silicon nitride (SiₓN_{y} such as Si₃N₄), silicon oxycarbonitride (SiOCN), silicon oxynitride (SiON), and/or silicon carbon nitride SiCN), among other examples.

Source/drain contacts 250 may be included in the bulk semiconductor region 206. The source/drain contacts 250 may be electrically coupled and/or physically coupled with the source/drain regions 214 of the bulk semiconductor device(s) 210. The source/drain contacts 250 may include vias, trenches, plugs, conductive columns, interconnects, and/or another type of conductive structures. The source/drain contacts 250 may include one or more conductive materials such as cobalt (Co), copper (Cu), titanium (Ti), ruthenium (Ru), aluminum (Al), a metal alloy, and/or another conductive material.

Source/drain contacts 252 may be included in the SOI region 204. The source/drain contacts 252 may be electrically coupled and/or physically coupled with the source/drain regions 234 of the SOI semiconductor device(s) 212. The source/drain contacts 252 may include vias, trenches, plugs, conductive columns, interconnects, and/or another type of conductive structure. The source/drain contacts 252 may include one or more conductive materials such as cobalt (Co), copper (Cu), titanium (Ti), ruthenium (Ru), aluminum (Al), a metal alloy, and/or another conductive material.

FIG. 2B illustrates a detailed cross-section view of the SOI layer stack in the SOI region 204 of the semiconductor device 200. As shown in FIG. 2B, the insulator layer 230 has a substantially flat top surface 254 and a scalloped bottom surface 256. The scalloped bottom surface 256 is located at an interface between the insulator layer 230 and the semiconductor grounding layer 228. Alternatively, the scalloped bottom surface 256 is located at an interface between the insulator layer 230 and the underlying bulk semiconductor substrate of the active semiconductor region 202. The scalloped bottom surface 256 includes a plurality of protrusions 258 that extend downward into the semiconductor grounding layer 228 and/or into the underlying bulk semiconductor substrate of the active semiconductor region 202. The scalloped bottom surface 256 results from the two-part technique that is used to form the insulator layer 230 and semiconductor layer 232, which is described in connection with FIGS. 3A-3M.

The protrusions 258 in the scalloped bottom surface 256 result in an average surface roughness (indicated as dimension D1 in FIG. 2B) for the scalloped bottom surface 256 that is included in a range of approximately 5 nanometers average roughness (Rₐ) to approximately 20 nanometers Rₐ. However, other values for the range are within the scope of the present disclosure. The flat top surface 254 is “flat” in that the average surface roughness of the flat top surface 254 is less than the average surface roughness of the scalloped bottom surface 254. For example, the flat top surface 254 has an average surface roughness less than approximately 5 nanometers Rₐ. In some implementations, the flat top surface 254 has an average surface roughness that is included in a range of greater than 0 nanometers Rₐ and less than approximately 2 nanometers Rₐ. However, other values for the range are within the scope of the present disclosure. In some implementations, the scalloped bottom surface 256 has a scallop pitch. At ends 260 of the scallops of the scalloped bottom surface 256, the scallop pitch may correspond to the pitch of the STI of the insulator layer 230. At troughs 262 of the scallops. the scallop pitch may correspond to approximately half (½) of the pitch of the STI of the insulator layer 230.

As further shown in FIG. 2B, the insulator layer 230 may have a dimension D2 corresponding to a thickness of the insulator layer 230. In some implementations, the thickness of the insulator layer 230 is included in a range of approximately 3 nanometers to approximately 2 microns. If the dimension D2 is less than approximately 3 nanometers, the insulator layer 230 may not provide sufficient electrical isolation for the SOI semiconductor devices 212 in the SOI region 204. If the dimension D2 is greater than approximately 2 nanometers, the height or thickness of the semiconductor device 200 may be unnecessarily increased. If the dimension D2 is included in the range of approximately 3 nanometers to approximately 2 microns, the insulator layer 230 may provide sufficient electrical isolation while enabling a sufficiently small size for the semiconductor device 200 to be achieved. However, other values for the dimension D2, and ranges other than approximately 3 nanometers to approximately 2 microns, are within the scope of the present disclosure.

As further shown in FIG. 2B, the semiconductor layer 232 may have a dimension D3 corresponding to a thickness of the semiconductor layer 232. In some implementations, the thickness of the semiconductor layer 232 is included in a range of approximately 50 nanometers to approximately 200 nanometers. However, other values for the range are within the scope of the present disclosure.

As indicated above, FIGS. 2A and 2B are provided as an example. Other examples may differ from what is described with regard to FIGS. 2A and 2B.

FIGS. 3A-3M are diagrams of an example implementation 300 of forming the hybrid substrate of the semiconductor device 200 described herein. In some implementations, one or more of the semiconductor processing tools 102-112 and/or the wafer/die transport tool 114 may be used to perform one or more of the semiconductor processing operations described in connection with FIGS. 3A-3M. In some implementations, one or more of the semiconductor processing operations described in connection with FIGS. 3A-3M may be performed using another semiconductor processing tool.

Turning to FIG. 3A, a bulk semiconductor substrate is provided. The bulk semiconductor substrate may be provided in the form of an active semiconductor region 202 of the semiconductor device 200. The active semiconductor region 202 may include a portion of a bulk semiconductor wafer such as a bulk silicon (Si) wafer.

As shown in FIG. 3B, a plurality of recesses 302 may be formed in the bulk semiconductor substrate of the active semiconductor region 202 in the SOI region 204 of the semiconductor device 200. The recesses 302 may be formed such that the recesses 302 are spaced apart in the bulk semiconductor substrate of the active semiconductor region 202. In some implementations, a pattern in a photoresist layer is used to etch the bulk semiconductor substrate of the active semiconductor region 202 to form the recesses 302. In these implementations, a deposition tool 102 may be used to form the photoresist layer on the bulk semiconductor substrate of the active semiconductor region 202. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the bulk semiconductor substrate of the active semiconductor region 202 based on the pattern to form the recesses 302 in the bulk semiconductor substrate of the active semiconductor region 202. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the bulk semiconductor substrate of the active semiconductor region 202 based on a pattern.

In some implementations, a dry etch technique is used in the etch operation. The dry etch technique may include a plasma-based etch and/or another type of dry etch technique. The dry etch technique may be used to form the recesses 302 such that the recesses 302 have substantially vertical sidewalls and to control the aspect ratio of the recesses 302, among other examples. Additionally and/or alternatively, another etch technique such as a wet chemical etch technique may be used to form the recesses 302.

As shown in FIG. 3C, a dielectric layer 304 may be formed on the bulk semiconductor substrate of the active semiconductor region 202. The dielectric layer 304 may be deposited in the recesses 302. The dielectric layer 304 may be formed by blanket deposition such that the dielectric layer 304 fully fills the recesses 302 and merges on top of the bulk semiconductor substrate of the active semiconductor region 202. A deposition tool 102 may be used to deposit the dielectric layer 304 using a PVD technique, an ALD technique, a CVD technique, an oxidation technique, another type of deposition technique described in connection with FIG. 1, and/or another suitable deposition technique. In some implementations, a planarization tool 110 may be used to planarize the dielectric layer 304 after the dielectric layer 304 is deposited. The dielectric layer 304 includes one or more dielectric materials, such as a silicon oxide (SiOₓ such as SiO₂), a silicon nitride (SiₓN_{y} such as Si₃N₄), silicon oxycarbonitride (SiOCN), silicon oxynitride (SiON), and/or silicon carbon nitride SiCN), among other examples.

As shown in FIG. 3D, an etch back operation may be performed to remove portions of the dielectric layer 304 from the recesses 302 such that the recesses 302 are only partially filled with the dielectric layer 304. The remaining portions of the dielectric layer 304 in the recesses 302 correspond to first portions 306 (first dielectric regions) of the insulator layer 230. In some implementations, a pattern in a photoresist layer is used to etch the dielectric layer 304 in the etch back operation to form the first portions 306. In these implementations, a deposition tool 102 may be used to form the photoresist layer on the dielectric layer 304. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the dielectric layer 304 based on the pattern to form the first portions 306 in the recesses 302. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the dielectric layer 304 based on a pattern.

In some implementations, a dry etch technique is used in the etch back operation. The dry etch technique may include a plasma-based etch and/or another type of dry etch technique. The dry etch technique may be used to minimize dishing in the top surface of the first portions 306, which enables the flat top surface 254 of the insulator layer 230 to be achieved. Additionally and/or alternatively, another etch technique such as a wet chemical etch technique may be used.

As shown in FIG. 3E, an epitaxial regrowth operation is performed to epitaxially grow a first portion 308 of the semiconductor layer 232 on the first portions 306 of the insulator layer 230. Epitaxial growth of the first portion 308 of the semiconductor layer 232 may be initiated on the sidewalls of the recesses 302 that are exposed above the first portions of the insulator layer 230. Performing the etch back operation described in connection with FIG. 3D provides a semiconductor substrate or seed layer on which to epitaxially grow the first portion 308 of the semiconductor layer 232 instead of growing the first portion 308 of the semiconductor layer 232 directly on the insulator layer 230, which might otherwise result in voids and/or dislocations forming between the insulator layer 230 and the semiconductor layer 232.

A deposition tool 102 may be used to deposit the first portion 308 of the semiconductor layer 232 using an epitaxial deposition technique. As the first portion 308 of the semiconductor layer 232 grows from the sidewalls of the recesses 302, the first portion 308 of the semiconductor layer 232 merges above the first portions 306 of the insulator layer 230 in the recesses 302 to form a first merged semiconductor layer. A cyclic deposition and anneal technique may be used to reduce, minimize, and/or prevent formation of voids in the first portion 308 of the semiconductor layer 232 above the first portions 306 of the insulator layer 230.

The cyclic deposition and anneal technique may include using a deposition tool 102 to perform one or more epitaxial deposition and anneal cycles to epitaxially grow the first portion 308 of the semiconductor layer 232 in a void-free manner. Each epitaxial deposition and anneal cycle includes an epitaxial deposition operation to grow a subset of the first portion 308 of the semiconductor layer 232, followed by an anneal operation to remove voids from the first portion 308 of the semiconductor layer 232. The quantity of epitaxial deposition and anneal cycles may be included in a range of 1 to 10 cycles in order to achieve the first merged semiconductor layer. However, other values for the range are within the scope of the present disclosure. The epitaxial deposition and anneal cycles may be performed at a pressure in a processing chamber of the deposition tool that is included in a range of approximately 3 torr to approximately 6 torr. However, other values for the range are within the scope of the present disclosure.

FIG. 3F illustrates an example temperature profile for an anneal operation of an epitaxial deposition and anneal cycle for forming the first portion 308 of the semiconductor layer 232. The temperature profile is illustrated as a function of time 310 and temperature 312. As shown in FIG. 3F, an anneal operation may include a high/low temperature profile in which the first portion 308 of the semiconductor layer 232 is annealed at different anneal temperatures for separate time durations. The high/low temperature profile enables voids to be removed from the first portion 308 of the semiconductor layer 232.

In the anneal operation, a temperature of the first portion 308 of the semiconductor layer 232 may be increased during a first temperature ramping duration 314. The temperature of the first portion 308 of the semiconductor layer 232 may be increased from an initial temperature to a first anneal temperature during the first temperature ramping duration 314. The ramp rate for the temperature of the first portion 308 of the semiconductor layer 232 during the first temperature ramping duration 314 may be included in a range of approximately 10 degrees Celsius to approximately 20 degrees Celsius. However, other values for the range are within the scope of the present disclosure.

Once the first anneal temperature is reached, the temperature of the first portion 308 of the semiconductor layer 232 may be maintained at the first anneal temperature during a first temperature dwell time duration 316. The first anneal temperature may be included in a range of approximately 950 degrees Celsius to approximately 1050 degrees Celsius. However, other values for the range are within the scope of the present disclosure.

In some implementations, a time duration of the first temperature dwell time duration 316 is included in a range of approximately 10 seconds to approximately 100 seconds. If the first temperature dwell time duration 316 is less than approximately 10 seconds, the first portion 308 of the semiconductor layer 232 may not be able to be effectively annealed, and voids may remain in the first portion 308 of the semiconductor layer 232. If the first temperature dwell time duration 316 is greater than approximately 100 seconds, a low wafer throughput may be achieved. The first temperature dwell time duration 316 may be included in the range of approximately 10 seconds to approximately 100 seconds to achieve an effective anneal for the first portion 308 of the semiconductor layer 232 while enabling a sufficiently high wafer throughput to be achieved. However, other values for the first temperature dwell time duration 316, and ranges other than approximately 10 seconds to approximately 100 seconds, are within the scope of the present disclosure.

After the completion of the first temperature dwell time duration 316, the temperature of the first portion 308 of the semiconductor layer 232 may be decreased during a second temperature ramping duration 318. The temperature of the first portion 308 of the semiconductor layer 232 may be decreased from the first anneal temperature to a second anneal temperature during the second temperature ramping duration 318. The second anneal temperature is less than the first anneal temperature. The ramp rate for the temperature of the first portion 308 of the semiconductor layer 232 during the second temperature ramping duration 318 may be included in a range of approximately-10 degrees Celsius to approximately-20 degrees Celsius. However, other values for the range are within the scope of the present disclosure.

Once the second anneal temperature is reached, the temperature of the first portion 308 of the semiconductor layer 232 may be maintained at the second anneal temperature during a second temperature dwell time duration 320. The second anneal temperature may be included in a range of approximately 750 degrees Celsius to approximately 950 degrees Celsius. However, other values for the range are within the scope of the present disclosure.

In some implementations, a time duration of the second temperature dwell time duration 320 is included in a range of approximately 10 seconds to approximately 100 seconds. If the second temperature dwell time duration 320 is less than approximately 10 seconds, the first portion 308 of the semiconductor layer 232 may not be able to be effectively annealed, and voids may remain in the first portion 308 of the semiconductor layer 232. If the second temperature dwell time duration 320 is greater than approximately 100 seconds, a low wafer throughput may be achieved. The second temperature dwell time duration 320 may be included in the range of approximately 10 seconds to approximately 100 seconds to achieve an effective anneal for the first portion 308 of the semiconductor layer 232 while enabling a sufficiently high wafer throughput to be achieved. However, other values for the second temperature dwell time duration 320, and ranges other than approximately 10 seconds to approximately 100 seconds, are within the scope of the present disclosure.

The temperature of the semiconductor device 200 may be maintained within a range of approximately 750 degrees Celsius to approximately 1050 degrees Celsius during an epitaxial growth and anneal cycle to enable the first portion 308 of the semiconductor layer 232 to be formed with minimal epitaxy defects while minimizing the likelihood of damage to the first portions 306 of the insulator layer 230. However, other values for the range are within the scope of the present disclosure.

As shown in FIG. 3G, an etch back operation may be performed on the first portion 308 of the semiconductor layer 232 such that the first portion 308 of the semiconductor layer 232 remains only on the first portions 306 of the insulator layer 230. In some implementations, the etch tool 108 performs the etch back operation, which may include a wet chemical etch, a dry etch (e.g., a plasma-based etch), and/or another type of etch. In some implementations, the etch back operation is performed in-situ using a cluster tool. In these implementations, the epitaxial regrowth operation is performed in a first processing chamber of the cluster tool (e.g., a deposition chamber or epitaxy chamber), and the semiconductor device 200 is transferred to a second chamber of the cluster tool (e.g., etch chamber) in which the etch back operation is performed without breaking the vacuum under which the semiconductor device 200 is maintained.

After the etch back operation, the thickness of the first portion 308 of the semiconductor layer 232 (corresponding to dimension D4 in FIG. 3G) may be included in a range of approximately 30 nanometers to approximately 200 nanometers to enable precise control over the thickness of the first portion 308 of the semiconductor layer 232 while reducing the likelihood of void formation in the insulator layer 230. The thickness of the first portion 308 of the semiconductor layer 232 may not be able to be precisely controlled less than approximately 30 nanometers, whereas voids may occur during formation of subsequent portions of the insulator layer 230 if the thickness of the first portion 308 of the semiconductor layer 232 is greater than approximately 200 nanometers. However, other values for the thickness of the first portion 308 of the semiconductor layer 232, and ranges other than approximately 30 nanometers to approximately 200 nanometers, are within the scope of the present disclosure.

As further shown in FIG. 3G, a first portion 306 of the insulator layer 230 may have a dimension D5 corresponding to a width of the first portion 306. In some implementations, the dimension D5 is included in a range of approximately 30 nanometers to approximately 200 nanometers to enable precise patterning of the recesses 302 in which the first portions 306 are formed, while enabling a second portion of the semiconductor layer 232 (that is subsequently formed) to fully merge above the first portions 306. The recesses 302 may not be able to be precisely patterned if the dimension D5 is less than approximately 30 nanometers, whereas voids may occur during formation of a second portion of the semiconductor layer 232 if the dimension D5 is greater than approximately 200 nanometers. However, other values for the dimension D5, and ranges other than approximately 30 nanometers to approximately 200 nanometers, are within the scope of the present disclosure.

As further shown in FIG. 3G, a dimension D6 may correspond to a spacing between first portions 306 of the insulator layer 230. In some implementations, the dimension D6 is included in a range of approximately 30 nanometers to approximately 200 nanometers to enable precise patterning of the recesses 302 in which the first portions 306 are formed, while enabling a second portion of the semiconductor layer 232 (that is subsequently formed) to fully merge above the first portions 306. The recesses 302 may not be able to be precisely patterned if the dimension D6 is less than approximately 30 nanometers, whereas voids may occur during formation of a second portion of the semiconductor layer 232 if the dimension D6 is greater than approximately 200 nanometers. However, other values for the dimension D6, and ranges other than approximately 30 nanometers to approximately 200 nanometers, are within the scope of the present disclosure.

As further shown in FIG. 3G, a dimension D7 may correspond to a pitch of the first portions 306 of the insulator layer 230. In some implementations, the dimension D7 is included in a range of approximately 60 nanometers to approximately 400 nanometers to enable precise patterning of the recesses 302 in which the first portions 306 are formed, while enabling a second portion of the semiconductor layer 232 (that is subsequently formed) to fully merge above the first portions 306. The recesses 302 may not be able to be precisely patterned if the dimension D7 is less than approximately 60 nanometers, whereas voids may occur during formation of a second portion of the semiconductor layer 232 if the dimension D7 is greater than approximately 400 nanometers. However, other values for the dimension D7, and ranges other than approximately 60 nanometers to approximately 400 nanometers, are within the scope of the present disclosure.

As indicated above, a two-part technique is used to form the insulator layer 230 and semiconductor layer 232 to minimize void formation in the semiconductor layer 232. FIGS. 3A-3G correspond to the first part of the two-part technique, where the first part includes forming the first portions 306 of the insulator layer 230 and the first portion 308 of the semiconductor layer 232. The second part, described in connection with FIGS. 3H-3M, corresponds to the second part of the two-part technique. The second part includes a similar set of operations, as illustrated and described in connection with FIGS. 3A-3G, that are performed to form second portions of the insulator layer 230 and a second portion of the semiconductor layer 232. The second portions of the insulator layer 230 merge with the first portions 306 of the insulator layer 230 to form a unified BOX layer. Similarly, the second portion of the semiconductor layer 232 merges with the first portion 308 of the semiconductor layer 232 to form a merged semiconductor layer 232 above the insulator layer 230. In this way, the SOI layer stack in the SOI region 204 of the semiconductor device 200 is formed.

The quantity of sequential steps or parts for forming the insulator layer 230 is an example, and other quantities of sequential steps or parts may be performed to form the insulator layer 230. As an example, a first part (e.g., a set of operations as illustrated and described in connection with FIGS. 3A-3G, a set of operations as illustrated and described in connection with FIGS. 3H-3M) may be performed to form first portions of the insulator layer 230, a second part (e.g., a set of operations as illustrated and described in connection with FIGS. 3A-3G, a set of operations as illustrated and described in connection with FIGS. 3H-3M) may be performed to form second portions of the insulator layer 230, and a third part (e.g., a set of operations as illustrated and described in connection with FIGS. 3A-3G, a set of operations as illustrated and described in connection with FIGS. 3H-3M) may be performed to form third portions of the insulator layer 230. As an example, a first part (e.g., a set of operations as illustrated and described in connection with FIGS. 3A-3G, a set of operations as illustrated and described in connection with FIGS. 3H-3M) may be performed to form first portions of the insulator layer 230, a second part (e.g., a set of operations as illustrated and described in connection with FIGS. 3A-3G, a set of operations as illustrated and described in connection with FIGS. 3H-3M) may be performed to form second portions of the insulator layer 230, a third part (e.g., a set of operations as illustrated and described in connection with FIGS. 3A-3G, a set of operations as illustrated and described in connection with FIGS. 3H-3M) may be performed to form third portions of the insulator layer 230, and a fourth part (e.g., a set of operations as illustrated and described in connection with FIGS. 3A-3G, a set of operations as illustrated and described in connection with FIGS. 3H-3M) may be performed to form fourth portions of the insulator layer 230.

As shown in FIG. 3H, a masking layer 322 may be formed over and/or on the semiconductor device 200. The masking layer 322 may include one or more layers in which a pattern may be formed. The one or more layers may include an oxide layer 324 (e.g., a silicon oxide (SiOₓ) layer), a nitride layer 326 (e.g., a silicon nitride (SiₓN_{y}) layer), and/or a photoresist layer 328, among other examples. A deposition tool 102 may be used to deposit the masking layer 322 using a PVD technique, an ALD technique, a CVD technique, an oxidation technique, another type of deposition technique described in connection with FIG. 1, and/or another suitable deposition technique. In some implementations, the planarization tool 110 may be used to planarize one or more layers of the masking layer 322 after the masking layer 322 is deposited.

As shown in FIG. 3I, a pattern 330 may be formed in the photoresist layer 328 of the masking layer 322. The pattern 330 may include openings in the photoresist layer 328, where the openings are located above and between the first portions 306 of the insulator layer 230. An exposure tool 104 may be used to expose the photoresist layer 328 to a radiation source to form the pattern 330 in the photoresist layer 328, and a developer tool 106 may be used to develop and remove portions of the photoresist layer 328 to expose the pattern 330. The openings may have a dimension D8 corresponding to a width of the openings, and another dimension D9 may correspond to a spacing between the openings. In some implementations, the dimension D8 and the dimension D9 are approximately a same value. In some implementations, the dimension D8 is greater than the dimension D9. The dimensions D8 and D9 may each be included in a range of approximately 30 nanometers to approximately 200 nanometers. However, other values for the range are within the scope of the present disclosure.

As shown in FIG. 3J, an etch tool 108 may be used to etch the bulk semiconductor substrate of the active semiconductor region 202 based on the pattern to form a second plurality of recesses 332 in the bulk semiconductor substrate of the active semiconductor region 202. The recesses 332 may be formed in between the first portions 306 of the insulator layer 230 and in between the first portion 308 of the semiconductor layer 232. The etch tool 108 is used to etch the bulk semiconductor substrate of the active semiconductor region 202 based on the pattern 330 to form the recesses 332. The pattern 330 may be first transferred to the oxide layer 324 and the nitride layer 326 of the masking layer 322, and the pattern 330 in the oxide layer 324 and the nitride layer 326 may be used to etch the bulk semiconductor substrate of the active semiconductor region 202 to form the recesses 332. In some implementations, a photoresist removal tool may be used to remove the remaining portions of the photoresist layer 328 (e.g., using a chemical stripper, plasma ashing, and/or another technique).

In some implementations, a dry etch technique is used in the etch operation. The dry etch technique may include a plasma-based etch and/or another type of dry etch technique. The dry etch technique may be used to form the recesses 332 such that the recesses 332 have substantially vertical sidewalls and to control the aspect ratio of the recesses 332, among other examples. Additionally and/or alternatively, another etch technique such as a wet chemical etch technique may be used to form the recesses 332.

As shown in FIG. 3K, a dielectric layer 334 may be formed on the masking layer 322. The dielectric layer 334 is deposited in the recesses 332. The dielectric layer 334 may be formed by blanket deposition such that the dielectric layer 334 fully fills the recesses 332 and merges on top of the nitride layer 326 of the masking layer 322. A deposition tool 102 may be used to deposit the dielectric layer 334 using a PVD technique, an ALD technique, a CVD technique, an oxidation technique, another type of deposition technique described in connection with FIG. 1, and/or another suitable deposition technique. In some implementations, a planarization tool 110 may be used to planarize the dielectric layer 334 after the dielectric layer 334 is deposited. The dielectric layer 334 includes one or more dielectric materials, such as a silicon oxide (SiOₓ such as SiO₂), a silicon nitride (SiₓN_{y} such as Si₃N₄), silicon oxycarbonitride (SiOCN), silicon oxynitride (SiON), and/or silicon carbon nitride SiCN), among other examples.

As shown in FIG. 3L, an etch back operation may be performed to remove portions of the dielectric layer 334 from the recesses 332 such that the recesses 332 are only partially filled with the dielectric layer 304. The oxide layer 324 and the nitride layer 326 of the masking layer 322 are also removed. The remaining portions of the dielectric layer 334 in the recesses 332 correspond to second portions 336 (second dielectric regions) of the insulator layer 230. The first portions 306 and the second portions 336 merge to form a continuous dielectric layer corresponding to the insulator layer 230. The merger of the first portions 306 and the second portions 336 results in the scalloped bottom surface 256 of the insulator layer 230.

In some implementations, a dry etch technique is used in the etch back operation. The dry etch technique may include a plasma-based etch and/or another type of dry etch technique. The dry etch technique may be used to minimize dishing in the top surface of the second portions 336, which enables the flat top surface 254 of the insulator layer 230 to be achieved. Additionally and/or alternatively, another etch technique such as a wet chemical etch technique may be used.

As shown in FIG. 3M, an epitaxial regrowth operation is performed to epitaxially grow a second portion of the semiconductor layer 232 that merges with the first portion 308 of the semiconductor layer 232 to form a merged semiconductor layer on the insulator layer 230. Epitaxial growth of the second portion of the semiconductor layer 232 may be initiated on the sidewalls of the recesses 332 that are exposed above the second portions 336 of the insulator layer 230. Performing the etch back operation described in connection with FIG. 3L provides a semiconductor substrate or seed layer on which to epitaxially grow the second portion of the semiconductor layer 232 instead of growing the second portion of the semiconductor layer 232 directly on the second portions 336 of the insulator layer 230, which might otherwise result in voids and/or dislocations forming between the insulator layer 230 and the semiconductor layer 232.

A deposition tool 102 may be used to deposit the second portion of the semiconductor layer 232 using an epitaxial deposition technique. As the second portion of the semiconductor layer 232 grows from the sidewalls of the recesses 332, the second portion of the semiconductor layer 232 merges with the first portion 308 of the semiconductor layer 232. A cyclic deposition, described in connection with FIGS. 3E and 3F, and anneal technique may be used to reduce, minimize, and/or prevent formation of voids in the second portion of the semiconductor layer 232 above the second portions 336 of the insulator layer 230.

As indicated above, FIGS. 3A-3M are provided as an example. Other examples may differ from what is described with regard to FIGS. 3A-3M.

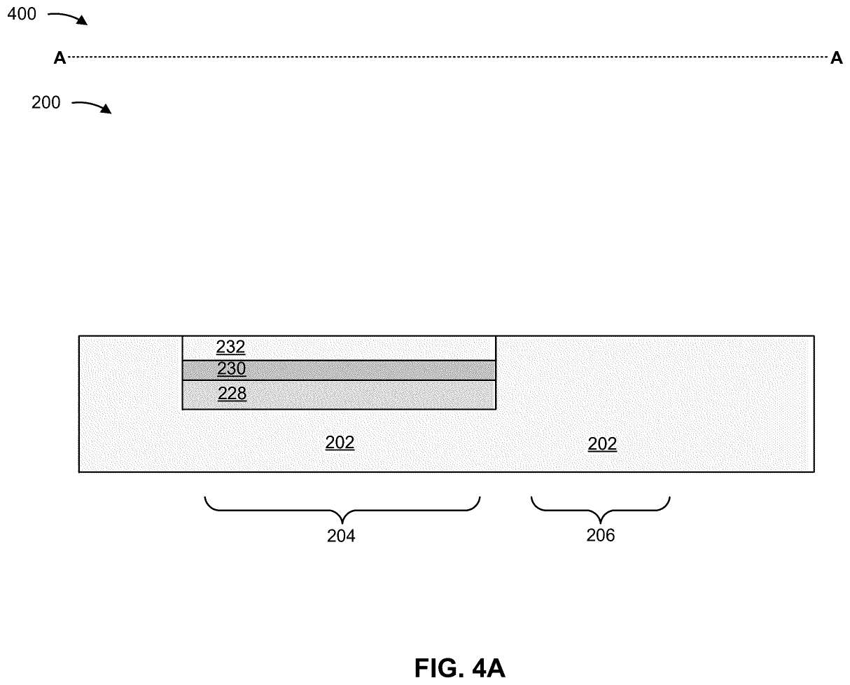

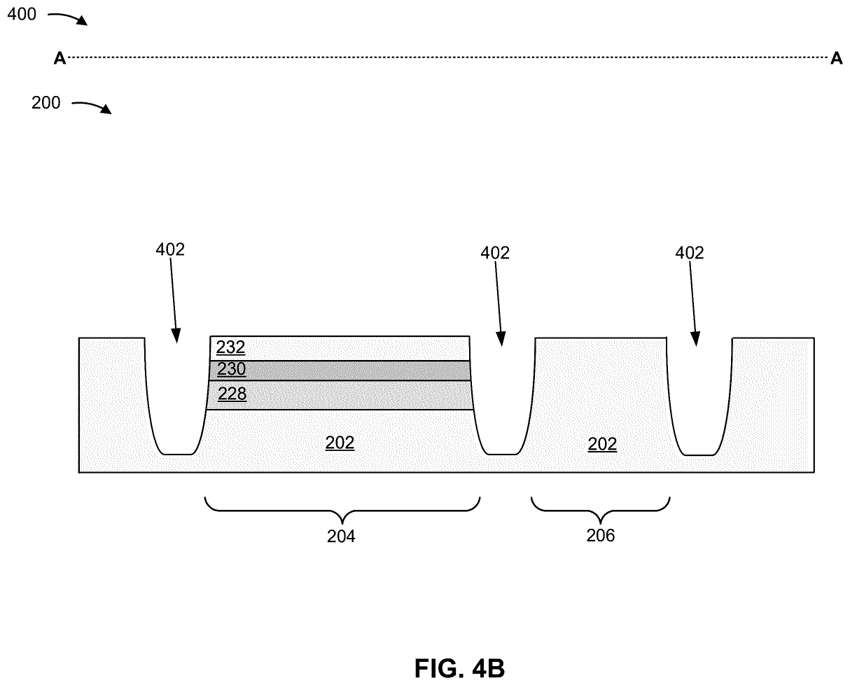

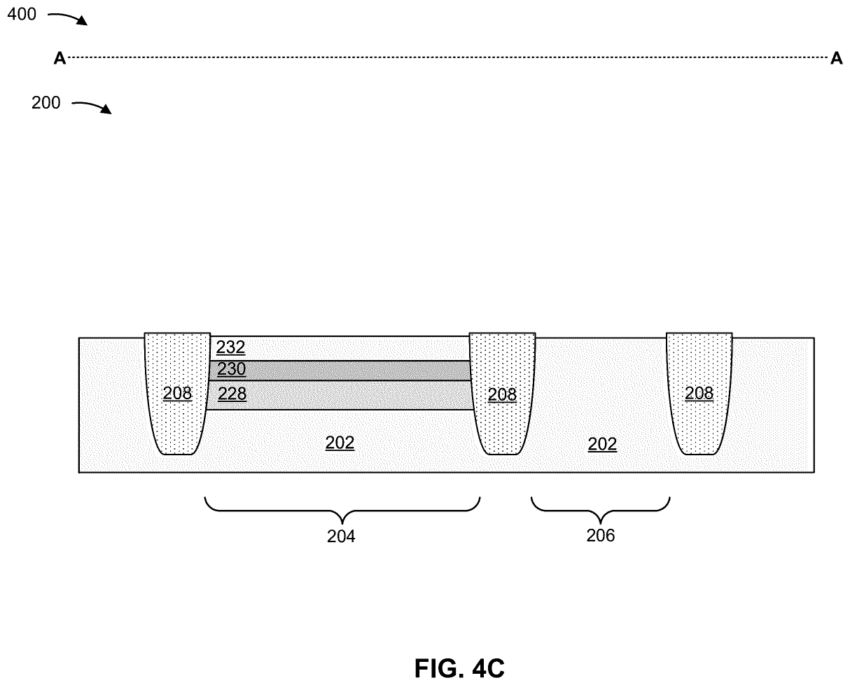

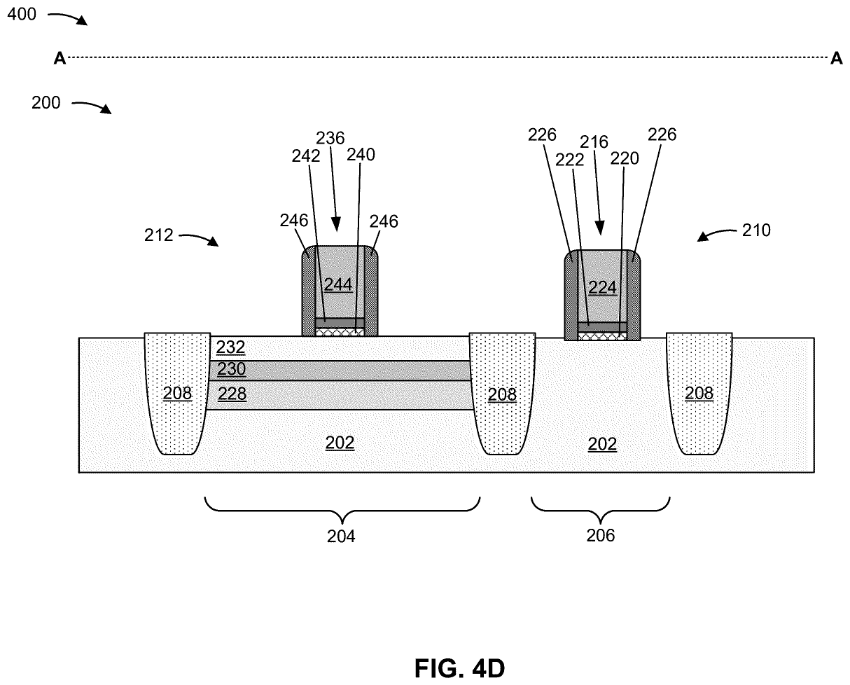

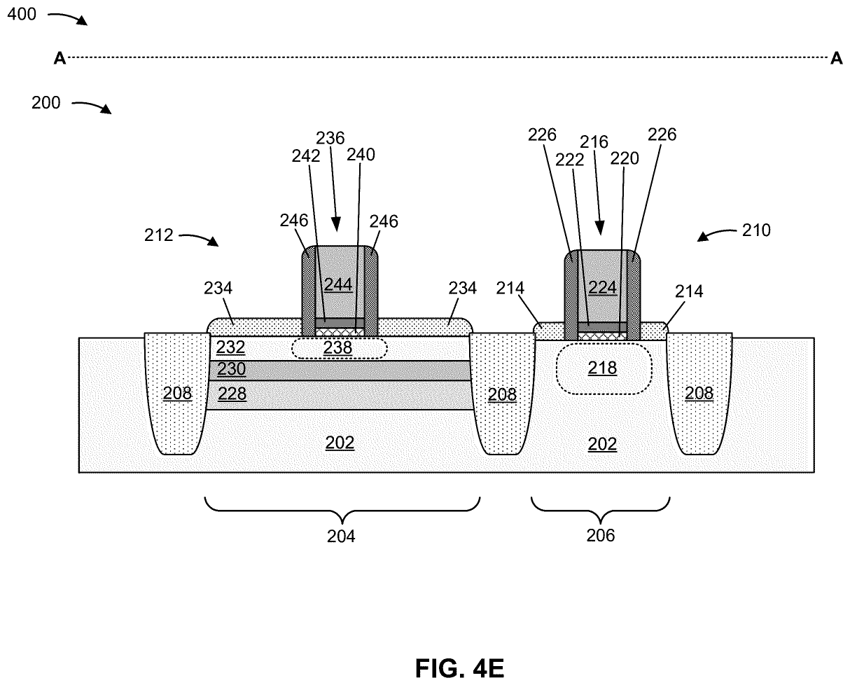

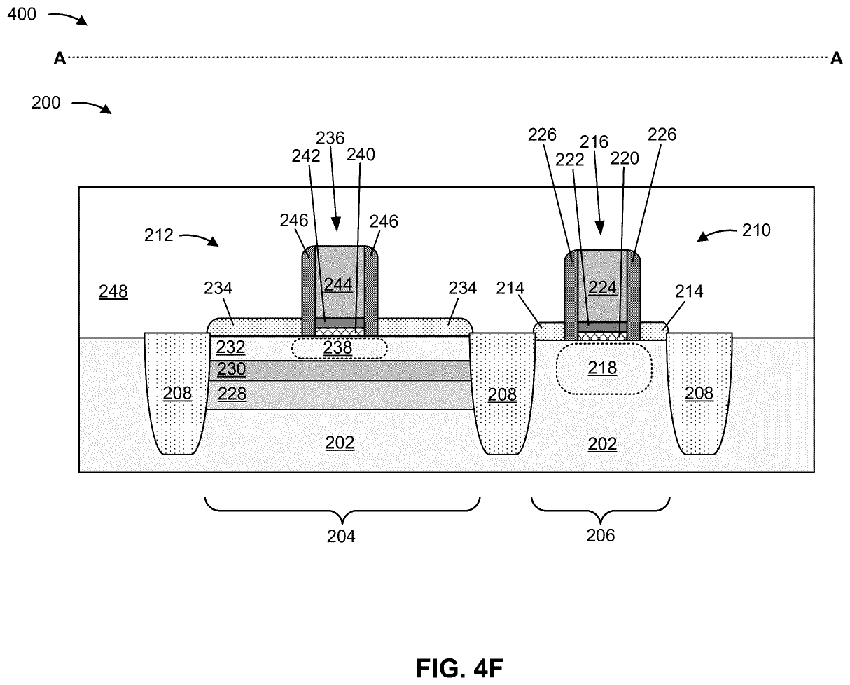

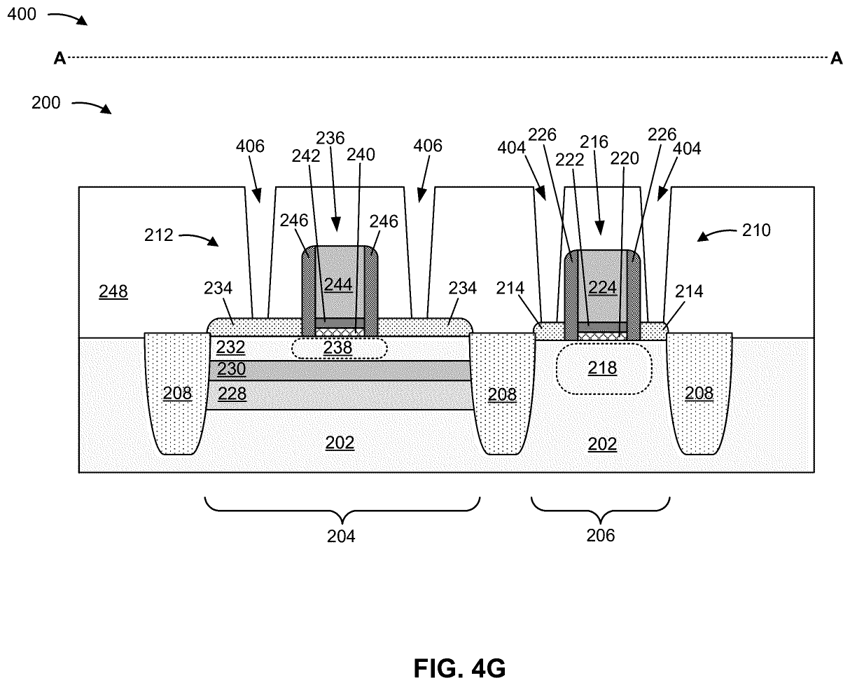

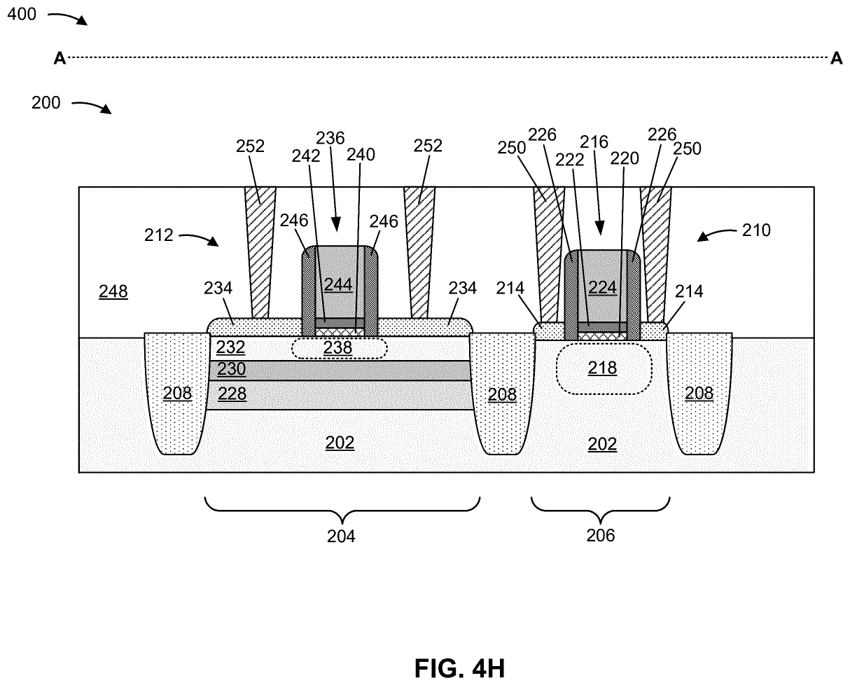

FIGS. 4A-4H are diagrams of an example implementation 400 of forming semiconductor devices on the hybrid substrate of the semiconductor device 200 described herein. In some implementations, one or more of the semiconductor processing tools 102-112 and/or the wafer/die transport tool 114 may be used to perform one or more of the semiconductor processing operations described in connection with FIGS. 4A-4H. In some implementations, one or more of the semiconductor processing operations described in connection with FIGS. 4A-4H may be performed using another semiconductor processing tool.

Turning to FIG. 4A, the hybrid substrate, including the bulk semiconductor region 206 and the SOI region 204, may be provided. The SOI region 204 may be formed using techniques described above in connection with FIGS. 3A-3M.

As shown in FIG. 4B, recesses 402 may be formed in the bulk semiconductor region 206 of the active semiconductor region 202. The recesses 402 may be formed on opposing sides of the bulk semiconductor region 206, on opposing sides of the SOI region 204, and/or between the bulk semiconductor region 206 and the SOI region 204.

In some implementations, a pattern in a photoresist layer is used to etch the bulk semiconductor substrate of the active semiconductor region 202 to form the recesses 402. In these implementations, a deposition tool 102 may be used to form the photoresist layer on the hybrid substrate of the semiconductor device 200. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch the bulk semiconductor substrate of the active semiconductor region 202 based on the pattern to form the recesses 402 in the bulk semiconductor substrate of the active semiconductor region 202. In some implementations, the etch operation includes a plasma etch operation, a wet chemical etch operation, and/or another type of etch operation. In some implementations, a photoresist removal tool may be used to remove the remaining portions of the photoresist layer (e.g., using a chemical stripper, plasma ashing, and/or another technique). In some implementations, a hard mask layer is used as an alternative technique for etching the bulk semiconductor substrate of the active semiconductor region 202 based on a pattern.

As shown in FIG. 4C, the recesses 402 are filled with a dielectric material to form the isolation regions 208 in the recesses 402. A deposition tool 102 may be used to deposit the isolation regions 208 using a PVD technique, an ALD technique, a CVD technique, an oxidation technique, another type of deposition technique described in connection with FIG. 1, and/or another suitable deposition technique. In some implementations, the planarization tool 110 may be used to planarize the isolation regions 208 after the isolation regions 208 are deposited.

As shown in FIG. 4D, a gate structure 216 of a bulk semiconductor device 210 may be formed over and/or on the active semiconductor region 202 in the bulk semiconductor region 206. The gate structure 216 may be formed between the isolation regions 208 on opposing sides of the bulk semiconductor region 206.

As further shown in FIG. 4D, a gate structure 236 of an SOI semiconductor device 212 may be formed over and/or on the semiconductor layer 232 of the SOI region 204. The gate structure 236 may be formed between the isolation regions 208 on opposing sides of the SOI region 204.

Forming a gate structure 216 and/or a gate structure 236 may include forming (e.g., using a deposition tool 102) a gate dielectric layer using suitable deposition techniques such as LPCVD or PECVD, among other examples, forming a hard mask layer (e.g., using a deposition tool 102) using CVD, PVD, ALD, or another suitable deposition process, and/or forming a gate electrode (e.g., using a deposition tool 102) using CVD, PVD, ALD, or another suitable deposition process, among other examples. Moreover, sidewall spacers 226 may be formed on the sidewalls of the gate structure 216, and sidewall spacers 246 may be formed on the sidewalls of the gate structure 236. The sidewall spacers 226 and/or 246 may be conformally deposited (e.g., using a deposition tool 102), then patterned (e.g., using a deposition tool 102, an exposure tool 104, and a developer tool 106), and etched (e.g., using an etch tool 108) to form the sidewall spacers 226 and/or 246.

As shown in FIG. 4E, source/drain regions 214 may be formed on opposing sides of the gate structure 216 in the bulk semiconductor region 206, and source/drain regions 234 may be formed on opposing sides of the gate structure 236. A deposition tool 102 may be used to epitaxially grow the source/drain regions 214 and/or 234. Additionally and/or alternatively, a deposition tool 102 may be used to form the source/drain regions 214 and/or 234 using another suitable deposition technique.

As shown in FIG. 4F, the dielectric region 248 may be formed over the semiconductor device 200. A deposition tool 102 may be used to deposit the dielectric region 248 using a PVD technique, an ALD technique, a CVD technique, an oxidation technique, another type of deposition technique described in connection with FIG. 1, and/or another suitable deposition technique. In some implementations, the planarization tool 110 may be used to planarize the dielectric region 248 after the dielectric region 248 is deposited.

As shown in FIG. 4G, openings (or recesses) 404 are formed through the dielectric region 248 and to the source/drain regions 214 such that the source/drain regions 214 are exposed through the openings 404. Openings (or recesses) 406 are formed through the dielectric region 248 and to the source/drain regions 234 such that the source/drain regions 234 are exposed through the openings 406.

In some implementations, a pattern in a photoresist layer is used to form the openings 404 and/or 406. In these implementations, a deposition tool 102 may be used to form the photoresist layer on the dielectric region 248. An exposure tool 104 may be used to expose the photoresist layer to a radiation source to pattern the photoresist layer. A developer tool 106 may be used to develop and remove portions of the photoresist layer to expose the pattern. An etch tool 108 may be used to etch into the dielectric region 248 to form the openings 404 and/or 406. In some implementations, the etch operation includes a plasma etch technique, a wet chemical etch technique, and/or another type of etch technique. In some implementations, a photoresist removal tool removes the remaining portions of the photoresist layer (e.g., using a chemical stripper, plasma ashing, and/or another technique). In some implementations, a hard mask layer is used as an alternative technique for forming the openings 404 and/or 406 based on a pattern.

As shown in FIG. 4H, source/drain contacts 250 are formed in the openings 404, and source/drain contacts 252 are formed in the openings 406. A deposition tool 102 and/or a plating tool 112 may be used to deposit the source/drain contacts 250 and/or 252 using a CVD technique, a PVD technique, an ALD technique, an electroplating technique, another deposition technique described above in connection with FIG. 1, and/or a deposition technique other than as described above in connection with FIG. 1. In some implementations, one or more additional layers are formed in the openings 404 and/or 406 prior to formation of the source/drain contacts 250 and/or 252. As an example, a metal silicide layer (e.g., titanium nitride (TiSiₓ) or another metal silicide layer) may be formed on the top surfaces of the source/drain regions 214 and/or 234 prior to formation of the source/drain contacts 250 and/or 252. As another example, one or more barrier layers may be formed on the bottom surfaces and/or on the sidewalls in the openings 404 and/or 406 prior to formation of the source/drain contacts 250 and/or 252. As another example, one or more adhesion layers may be formed on the bottom surfaces and/or on the sidewalls in the openings 404 and/or 406 prior to formation of the source/drain contacts 250 and/or 252.

As indicated above, FIGS. 4A-4H are provided as an example. Other examples may differ from what is described with regard to FIGS. 4A-4H.

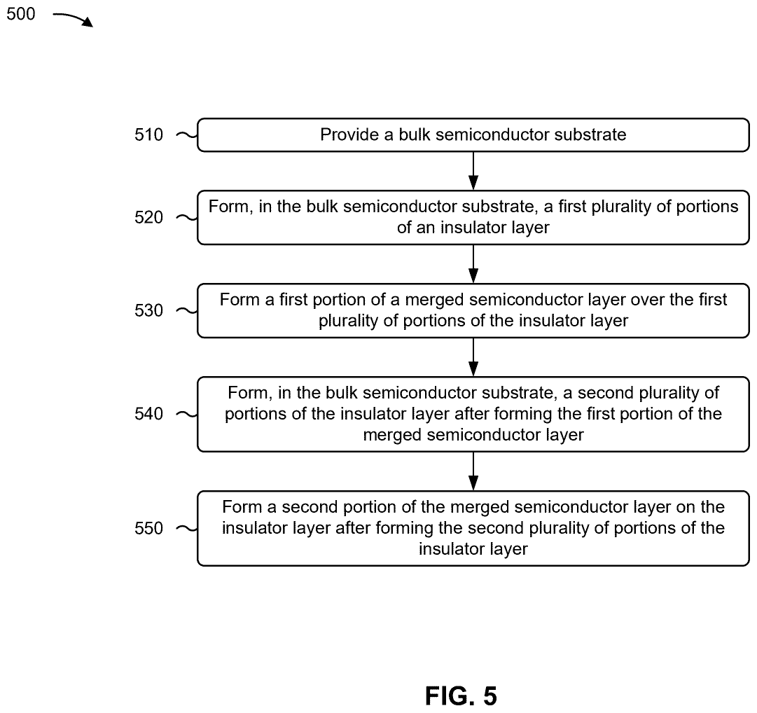

FIG. 5 is a flowchart of an example process 500 associated with forming a hybrid substrate described herein. In some implementations, one or more process blocks of FIG. 5 are performed using one or more semiconductor processing tools.

As shown in FIG. 5, process 500 may include providing a bulk semiconductor substrate (block 510). For example, one or more semiconductor processing tools may be used to provide an active semiconductor region 202 in the form of a bulk semiconductor substrate, as described herein.

As further shown in FIG. 5, process 500 may include forming, in the bulk semiconductor substrate, a first plurality of portions of an insulator layer (block 520). For example, one or more semiconductor processing tools may be used to form, in the bulk semiconductor substrate (e.g., in the active semiconductor region 202), a first plurality of portions 306 of an insulator layer 230, as described herein.

As further shown in FIG. 5, process 500 may include forming a first portion of a merged semiconductor layer over the first plurality of portions of the insulator layer (block 530). For example, one or more semiconductor processing tools may be used to form a first portion 308 of a merged semiconductor layer 232 over the first plurality of portions 306 of the insulator layer 230, as described herein.

As further shown in FIG. 5, process 500 may include forming, in the bulk semiconductor substrate, a second plurality of portions of the insulator layer after forming the first portion of the merged semiconductor layer (block 540). For example, one or more semiconductor processing tools may be used to form, in the bulk semiconductor substrate (e.g., in the active semiconductor region 202), a second plurality of portions 336 of the insulator layer 230 after forming the first portion 308 of the merged semiconductor layer 232, as described herein.

As further shown in FIG. 5, process 500 may include forming a second portion of the merged semiconductor layer on the insulator layer after forming the second plurality of portions of the insulator layer (block 550). For example, one or more semiconductor processing tools may be used to form a second portion of the merged semiconductor layer 232 on the insulator layer 230 after forming the second plurality of portions 336 of the insulator layer 230, as described herein.

Process 500 may include additional implementations, such as any single implementation or any combination of implementations described below and/or in connection with one or more other processes described elsewhere herein.

In a first implementation, forming the second plurality of portions 336 of the insulator layer 230 includes forming the second plurality of portions 336 of the insulator layer 230 in between the first plurality of portions 306 of the insulator layer 230.

In a second implementation, alone or in combination with the first implementation, process 500 includes forming a plurality of recesses 302 in the bulk semiconductor substrate (e.g., in the active semiconductor region 202), where forming the first plurality of portions 306 of the insulator layer 230 includes forming the first plurality of portions 306 of the insulator layer 230 in the plurality of recesses 302.

In a third implementation, alone or in combination with one or more of the first and second implementations, a portion of the insulator layer 230, of the first plurality of portions 306 of the insulator layer 230, occupies a portion of a recess 302 of the plurality of recesses 302, and forming the first portion 308 of the merged semiconductor layer 232 includes epitaxially growing the first portion 308 of the merged semiconductor layer 232 in an unfilled portion of the recess 302 over the portion 306 of the insulator layer 230.

In a fourth implementation, alone or in combination with one or more of the first through third implementations, epitaxially growing the first portion 308 of the merged semiconductor layer 232 includes epitaxially growing the first portion 308 of the merged semiconductor layer 232 on sidewalls of the unfilled portion of the recess 302.

In a fifth implementation, alone or in combination with one or more of the first through fourth implementations, forming the first portion 308 of the merged semiconductor layer 232 includes performing a plurality of deposition and anneal cycles to form the first portion 308 of the merged semiconductor layer 232, where a deposition and anneal cycle, of the plurality of deposition and anneal cycles, includes an epitaxial deposition operation to deposit material of the first portion 308 of the merged semiconductor layer 232, and an anneal operation to anneal the material of the first portion 308 of the merged semiconductor layer 232.

In a sixth implementation, alone or in combination with one or more of the first through fifth implementations, the anneal operation includes annealing the material of the first portion 308 of the merged semiconductor layer 232 at a first anneal temperature for a first time duration (e.g., a first temperature dwell time duration 316), and annealing the material of the first portion of the merged semiconductor layer at a second anneal temperature for a second time duration (e.g., a second temperature dwell time duration 320).

In a seventh implementation, alone or in combination with one or more of the first through sixth implementations, the first anneal temperature is greater than the second anneal temperature.

Although FIG. 5 shows example blocks of process 500, in some implementations, process 500 includes additional blocks, fewer blocks, different blocks, or differently arranged blocks than those depicted in FIG. 5. Additionally, or alternatively, two or more of the blocks of process 500 may be performed in parallel.

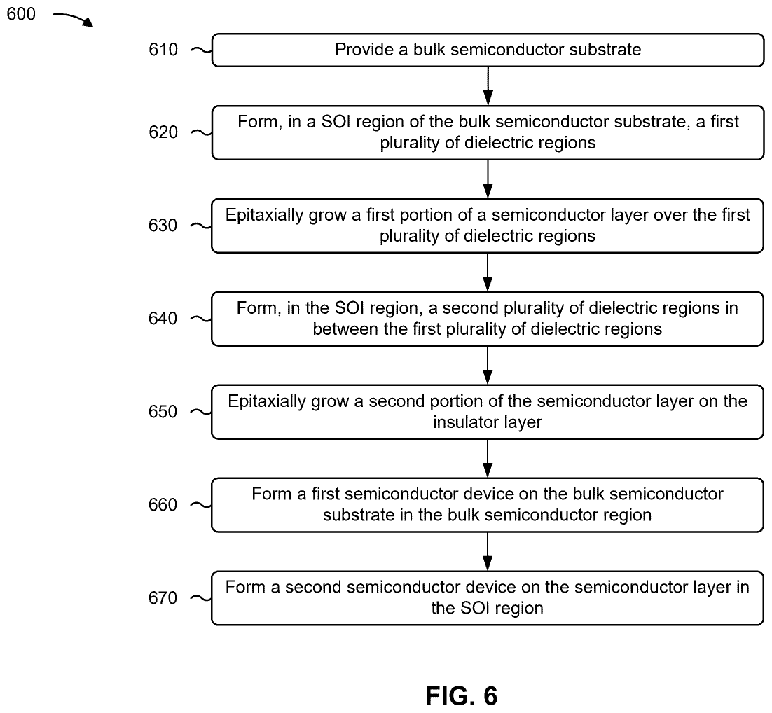

FIG. 6 is a flowchart of an example process 600 associated with forming a hybrid substrate described herein. In some implementations, one or more process blocks of FIG. 6 are performed using one or more semiconductor processing tools.

As shown in FIG. 6, process 600 may include providing a bulk semiconductor substrate (block 610). For example, one or more semiconductor processing tools may be used to provide an active semiconductor region 202 that is includes a bulk semiconductor substrate, as described herein.

As further shown in FIG. 6, process 600 may include forming, in an SOI region of the bulk semiconductor substrate, a first plurality of dielectric regions (block 720). For example, one or more semiconductor processing tools may be used to form, in an SOI region 204 of the bulk semiconductor substrate (e.g., of the active semiconductor region 202), a first plurality of dielectric regions (e.g., first portions 306), as described herein. In some implementations, the SOI region 204 is adjacent to a bulk semiconductor region 206 of the bulk semiconductor substrate (e.g., of the active semiconductor region 202).

As further shown in FIG. 6, process 600 may include epitaxially growing a first portion of a semiconductor layer over the first plurality of dielectric regions (block 630). For example, one or more semiconductor processing tools may be used to epitaxially grow a first portion of a semiconductor layer 232 over the first plurality of dielectric regions, as described herein.

As further shown in FIG. 6, process 600 may include forming, in the SOI region, a second plurality of dielectric regions in between the first plurality of dielectric regions (block 640). For example, one or more semiconductor processing tools may be used to form, in the SOI region 204, a second plurality of dielectric regions (e.g., second portions 336) in between the first plurality of dielectric regions, as described herein. In some implementations, the first plurality of dielectric regions and the second plurality of dielectric regions merge to form an insulator layer 230 in the SOI region 204.

As further shown in FIG. 6, process 600 may include epitaxially growing a second portion of the semiconductor layer on the insulator layer (block 650). For example, one or more semiconductor processing tools may be used to epitaxially grow a second portion of the semiconductor layer 232 on the insulator layer 230, as described herein.

As further shown in FIG. 6, process 600 may include forming a first semiconductor device on the bulk semiconductor substrate in the bulk semiconductor region (block 660). For example, one or more semiconductor processing tools may be used to form a first semiconductor device (e.g., a bulk semiconductor device 210) in the bulk semiconductor region 206 of the active semiconductor region 202, as described herein.

As further shown in FIG. 6, process 600 may include forming a second semiconductor device on the semiconductor layer in the SOI region (block 670). For example, one or more of the semiconductor processing tools 102-112 may be used to form a second semiconductor device (e.g., an SOI semiconductor device 212) on the semiconductor layer 232 in the SOI region 204, as described herein.

Process 600 may include additional implementations, such as any single implementation or any combination of implementations described below and/or in connection with one or more other processes described elsewhere herein.

In a first implementation, process 600 includes forming a first plurality of recesses 302 in the bulk semiconductor substrate (e.g., in the active semiconductor region 202) in the SOI region 204, where forming the first plurality of dielectric regions includes forming the first plurality of dielectric regions in the first plurality of recesses 302, and forming, after forming the first plurality of recesses 302, a second plurality of recesses 332 in the bulk semiconductor substrate (e.g., in the active semiconductor region 202) in the SOI region 204, where forming the second plurality of dielectric regions includes forming the second plurality of dielectric regions in the second plurality of recesses 332.

In a second implementation, alone or in combination with the first implementation, forming the second plurality of recesses 332 includes forming the second plurality of recesses 332 after forming the first plurality of dielectric regions in the first plurality of recesses 302.

In a third implementation, alone or in combination with one or more of the first and second implementations, forming the first plurality of dielectric regions in the first plurality of recesses 302 includes filling the first plurality of recesses with a dielectric layer 304, and performing a dry etch operation to remove first portions of the dielectric layer 304 from the first plurality of recesses 302, where second portions of the dielectric layer 304, remaining in the first plurality of recesses 302 after the dry etch operation, correspond to the first plurality of dielectric regions.

In a fourth implementation, alone or in combination with one or more of the first through third implementations, forming the first plurality of recesses 302 includes performing a first dry etch operation to form the first plurality of recesses 302, and forming the second plurality of recesses 332 includes performing a second dry etch operation to form the second plurality of recesses 332.

In a fifth implementation, alone or in combination with one or more of the first through fourth implementations, forming the second plurality of dielectric regions in the second plurality of recesses 332 includes filling the second plurality of recesses 332 with a dielectric layer 334, and performing a dry etch operation to remove first portions of the dielectric layer 334 from the second plurality of recesses 332, where second portions of the dielectric layer 334, remaining in the second plurality of recesses 332 after the dry etch operation, correspond to the second plurality of dielectric regions.

In a sixth implementation, alone or in combination with one or more of the first through fifth implementations, epitaxially growing the second portion of the semiconductor layer 232 includes epitaxially growing the second portion of the semiconductor layer 232 on sidewalls of the second plurality of recesses 332 above the second plurality of dielectric regions.

In a seventh implementation, alone or in combination with one or more of the first through sixth implementations, epitaxially growing the first portion 308 of the semiconductor layer 232 includes depositing, using an epitaxial deposition technique, the first portion 308 of the semiconductor layer 232, and performing an anneal operation on the first portion 308 of the semiconductor layer 232.

In an eighth implementation, alone or in combination with one or more of the first through seventh implementations, the anneal operation includes increasing a temperature of the first portion 308 of the semiconductor layer 232 during a first temperature ramping duration 314, where the temperature of the first portion 308 of the semiconductor layer 232 is increased to a first anneal temperature, maintaining the temperature of the first portion 308 of the semiconductor layer 232 at the first anneal temperature during a first temperature dwell time duration 316, decreasing the temperature of the first portion 308 of the semiconductor layer 232 during a second temperature ramping duration 318, where the temperature of the first portion 308 of the semiconductor layer 232 is decreased from the first anneal temperature to a second anneal temperature, and maintaining the temperature of the first portion 308 of the semiconductor layer 232 at the second anneal temperature during a second temperature dwell time duration 320.

Although FIG. 6 shows example blocks of process 600, in some implementations, process 600 includes additional blocks, fewer blocks, different blocks, or differently arranged blocks than those depicted in FIG. 6. Additionally, or alternatively, two or more of the blocks of process 600 may be performed in parallel.

In this way, a two-part technique is used to form an SOI region in a bulk semiconductor substrate with minimal to no dislocation or void formation. The bulk semiconductor substrate may be patterned and etched to form recesses in the bulk semiconductor substrate. The recesses are filled with first portions of an insulator layer of the SOI region, and the first portions are then etched back such that the first portions occupy only a bottom portion of the recesses such that semiconductor material of the sidewalls of the recesses is exposed. The semiconductor material of the sidewalls of the recesses provides an epitaxial growth substrate on which a top semiconductor layer is epitaxially grown over the first portions in the recesses. Subsequently, recesses between the first portions are formed through the top semiconductor layer into the bulk semiconductor substrate and filled in with second portions of the insulator layer using similar techniques. An epitaxial regrowth operation is performed to regrow and merge the top semiconductor layer over the insulator layer.

As described in greater detail above, some implementations described herein provide a method. The method includes providing a bulk semiconductor substrate. The method includes forming, in the bulk semiconductor substrate, a first plurality of portions of an insulator layer. The method includes forming a first portion of a merged semiconductor layer over the first plurality of portions of the insulator layer. The method includes forming, in the bulk semiconductor substrate, a second plurality of portions of the insulator layer after forming the first portion of the merged semiconductor layer. The method includes forming a second portion of the merged semiconductor layer on the insulator layer after forming the second plurality of portions of the insulator layer.

As described in greater detail above, some implementations described herein provide a method. The method includes providing a bulk semiconductor substrate. The method includes forming, in an SOI region of the bulk semiconductor substrate, a first plurality of dielectric regions, where the SOI region is adjacent to a bulk semiconductor region of the bulk semiconductor substrate. The method includes epitaxially growing a first portion of a semiconductor layer over the first plurality of dielectric regions. The method includes forming, in the SOI region, a second plurality of dielectric regions in between the first plurality of dielectric regions, where the first plurality of dielectric regions and the second plurality of dielectric regions merge to form an insulator layer in the SOI region. The method includes epitaxially growing a second portion of the semiconductor layer on the insulator layer. The method includes forming a first semiconductor device on the bulk semiconductor substrate in the bulk semiconductor region. The method includes forming a second semiconductor device on the semiconductor layer in the SOI region.

As described in greater detail above, some implementations described herein provide a semiconductor device. The semiconductor device includes a bulk semiconductor region, comprising, a first portion of a semiconductor substrate a first device over the first portion of the semiconductor substrate. The semiconductor device includes an SOI region that includes a second portion of the semiconductor substrate, an insulator layer over the second portion of the semiconductor substrate, a semiconductor layer over the insulator layer, and a second device over the semiconductor layer, where the insulator layer includes a flat top surface a scalloped bottom surface.

The foregoing outlines features of several embodiments so that those skilled in the art may better understand the aspects of the present disclosure. Those skilled in the art should appreciate that they may readily use the present disclosure as a basis for designing or modifying other processes and structures for carrying out the same purposes and/or achieving the same advantages of the embodiments introduced herein. Those skilled in the art should also realize that such equivalent constructions do not depart from the spirit and scope of the present disclosure, and that they may make various changes, substitutions, and alterations herein without departing from the spirit and scope of the present disclosure.

What is claimed is:

1. A method, comprising:
providing a bulk semiconductor substrate;
forming, in the bulk semiconductor substrate, a first plurality of portions of an insulator layer;
forming a first portion of a merged semiconductor layer over the first plurality of portions of the insulator layer;
forming, in the bulk semiconductor substrate, a second plurality of portions of the insulator layer after forming the first portion of the merged semiconductor layer; and
forming a second portion of the merged semiconductor layer on the insulator layer after forming the second plurality of portions of the insulator layer.

2. The method of claim 1, wherein forming the second plurality of portions of the insulator layer comprises:
forming the second plurality of portions of the insulator layer in between the first plurality of portions of the insulator layer.

3. The method of claim 1, further comprising:
forming a plurality of recesses in the bulk semiconductor substrate,
wherein forming the first plurality of portions of the insulator layer comprises:
forming the first plurality of portions of the insulator layer in the plurality of recesses.

4. The method of claim 3, wherein a portion of the insulator layer, of the first plurality of portions of the insulator layer, occupies a portion of a recess of the plurality of recesses; and
wherein forming the first portion of the merged semiconductor layer comprises:
epitaxially growing the first portion of the merged semiconductor layer in an unfilled portion of the recess over the portion of the insulator layer.

5. The method of claim 4, wherein epitaxially growing the first portion of the merged semiconductor layer comprises:
epitaxially growing the first portion of the merged semiconductor layer on sidewalls of the unfilled portion of the recess.

6. The method of claim 1, wherein forming the first portion of the merged semiconductor layer comprises:
performing a plurality of deposition and anneal cycles to form the first portion of the merged semiconductor layer,
wherein a deposition and anneal cycle, of the plurality of deposition and anneal cycles, comprises:
an epitaxial deposition operation to deposit material of the first portion of the merged semiconductor layer; and
an anneal operation to anneal the material of the first portion of the merged semiconductor layer.

7. The method of claim 6, wherein the anneal operation comprises:
annealing the material of the first portion of the merged semiconductor layer at a first anneal temperature for a first time duration; and
annealing the material of the first portion of the merged semiconductor layer at a second anneal temperature for a second time duration.

8. The method of claim 7, wherein the first anneal temperature is greater than the second anneal temperature.

9. A method, comprising:
providing a bulk semiconductor substrate;
forming, in a semiconductor on insulator (SOI) region of the bulk semiconductor substrate, a first plurality of dielectric regions,
wherein the SOI region is adjacent to a bulk semiconductor region of the bulk semiconductor substrate;
epitaxially growing a first portion of a semiconductor layer over the first plurality of dielectric regions;
forming, in the SOI region, a second plurality of dielectric regions in between the first plurality of dielectric regions,
wherein the first plurality of dielectric regions and the second plurality of dielectric regions merge to form an insulator layer in the SOI region;
epitaxially growing a second portion of the semiconductor layer on the insulator layer;
forming a first semiconductor device on the bulk semiconductor substrate in the bulk semiconductor region; and
forming a second semiconductor device on the semiconductor layer in the SOI region.

10. The method of claim 9, further comprising:
forming a first plurality of recesses in the bulk semiconductor substrate in the SOI region,
wherein forming the first plurality of dielectric regions comprises:
forming the first plurality of dielectric regions in the first plurality of recesses; and
forming, after forming the first plurality of recesses, a second plurality of recesses in the bulk semiconductor substrate in the SOI region,
wherein forming the second plurality of dielectric regions comprises:
forming the second plurality of dielectric regions in the second plurality of recesses.

11. The method of claim 10, wherein forming the second plurality of recesses comprises:
forming the second plurality of recesses after forming the first plurality of dielectric regions in the first plurality of recesses.

12. The method of claim 10, wherein forming the first plurality of dielectric regions in the first plurality of recesses comprises:
filling the first plurality of recesses with a dielectric layer; and
performing a dry etch operation to remove first portions of the dielectric layer from the first plurality of recesses,
wherein second portions of the dielectric layer, remaining in the first plurality of recesses after the dry etch operation, correspond to the first plurality of dielectric regions.

13. The method of claim 10, wherein forming the first plurality of recesses comprises:
performing a first dry etch operation to form the first plurality of recesses; and wherein forming the second plurality of recesses comprises:
performing a second dry etch operation to form the second plurality of recesses.

14. The method of claim 10, wherein forming the second plurality of dielectric regions in the second plurality of recesses comprises:
filling the second plurality of recesses with a dielectric layer; and
performing a dry etch operation to remove first portions of the dielectric layer from the second plurality of recesses,
wherein second portions of the dielectric layer, remaining in the second plurality of recesses after the dry etch operation, correspond to the second plurality of dielectric regions.

15. The method of claim 10, wherein epitaxially growing the second portion of the semiconductor layer comprises:
epitaxially growing the second portion of the semiconductor layer on sidewalls of the second plurality of recesses above the second plurality of dielectric regions.

16. The method of claim 9, wherein epitaxially growing the first portion of the semiconductor layer comprises:
depositing, using an epitaxial deposition technique, the first portion of the semiconductor layer; and
performing an anneal operation on the first portion of the semiconductor layer.

17. The method of claim 16, wherein the anneal operation comprises:
increasing a temperature of the first portion of the semiconductor layer during a first temperature ramping duration,
wherein the temperature of the first portion of the semiconductor layer is increased to a first anneal temperature;
maintaining the temperature of the first portion of the semiconductor layer at the first anneal temperature during a first temperature dwell time duration;
decreasing the temperature of the first portion of the semiconductor layer during a second temperature ramping duration,
wherein the temperature of the first portion of the semiconductor layer is decreased from the first anneal temperature to a second anneal temperature; and
maintaining the temperature of the first portion of the semiconductor layer at the second anneal temperature during a second temperature dwell time duration.

18. A semiconductor device, comprising:
a bulk semiconductor region, comprising:
a first portion of a semiconductor substrate;
a first device over the first portion of the semiconductor substrate; and
a semiconductor on insulator (SOI) region, comprising:
a second portion of the semiconductor substrate;
an insulator layer over the second portion of the semiconductor substrate;
a semiconductor layer over the insulator layer; and
a second device over the semiconductor layer,
wherein the insulator layer comprises:
a flat top surface; and
a scalloped bottom surface.

19. The semiconductor device of claim 18, wherein a thickness of the insulator layer is included in a range of approximately 3 nanometers to approximately 2 microns.

20. The semiconductor device of claim 18, wherein the scalloped bottom surface of the insulator layer is located at an interface between the insulator layer and a grounding layer under the insulator layer.
